(19) United States
(12) Patent Application Publication
(10) Pub. No.: US 2008/0002165 A1
(43) Pub. Date: Jan. 3, 2008

(54) Method And Apparatus For Producing Printed-Circuit-Board

(75) Inventor: Yoshiharu Sasaki, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: Fujifilm Corporation, Tokyo (JP)

(21) Appl. No.: 11/667,665

(22) PCT Filed: Nov. 4, 2005
(86) PCT No.: PCT/JP05/20675

§ 371 Date: May 14, 2007

(30) Foreign Application Priority Data
Nov. 12, 2004 (JP) 2004-328901

(51) Int. Cl. G03B 27/42; G03F 7/20; H05K 3/00; H05K 3/06

(52) U.S. Cl. 355/40; 355/53; 430/30

(57) ABSTRACT

Printed circuit boards having patterns of uniform line width can be produced. A lamination apparatus superposes a resist layer on a substrate. Further, the substrate is exposed to light carrying information representing lamination date/time. An exposure apparatus reads out the lamination date/time information before performing exposure and judges whether passage time from the lamination to the current time is within the range of predetermined hold time. If the judgment is NO, the exposure apparatus issues a warning to notify an operator that the passage time from the lamination to the current time is not within the range of the predetermined hold time. The operator may remove the substrate from the exposure apparatus because it is impossible to form a pattern of desirable line width on the substrate.

### TECHNICAL FIELD

The present invention relates to a method and an apparatus for producing printed circuit boards, which are produced by performing a lamination process, an exposure process and a development process.

### BACKGROUND ART

Generally, printed circuit boards are produced by performing the following processes. First, a lamination process is performed. In the lamination process, a dry film resist layer (hereinafter, simply referred to as a resist layer) is superposed on a conductive layer (for example, thin copper film) formed on a substrate, the conductive layer being a layer in which a circuit pattern will be formed. The dry film resist layer is made of a photosensitive material, which is cured by photopolymerization if the material is irradiated with light. Next, an exposure process is performed. In the exposure process, the resist layer is exposed to a light beam in a pattern which has the same shape as that of a circuit pattern. Then, in a development process, a portion of the resist layer, the portion which was not irradiated with the light beam, is removed and a pattern (hereinafter, referred to as a resist pattern) that has the same shape as the circuit pattern is formed. After the resist pattern is formed, an etching process for etching the conductive layer is performed by using the resist pattern as a mask. Then, a circuit pattern is formed in the conductive layer by removing the resist layer.

Further, a lamination process is performed. The lamination process is a process of superposing a solder resist layer by applying a solder resist, which is curable by irradiation with light. After the lamination process, the solder resist layer is half-cured. The solder resist layer is exposed to a light beam that has the same shape as a pattern having an opening for an electrode portion, the periphery of the upper surface of the electrode portion being coated to form a predetermined width of coating. Then, an unirradiated portion of the solder resist layer, which has not been irradiated with the light beam, is removed by developing the solder resist layer. After the removal, the solder resist layer is completely cured. After then, a nickel-gold plating layer or the like is formed to improve the wettability of solder. Accordingly, a printed circuit board is completed.

Further, conventionally, various exposure apparatuses that perform image exposure using light beams modulated based on image data have been proposed. In the exposure apparatuses, spatial light modulation devices, such as a digital micromirror device (DMD), are utilized. As one of the uses of such exposure apparatuses, application of the exposure apparatus to the process for producing printed circuit boards is well known (please refer to Japanese Unexamined Patent Publication No. 2004-1244, for example).

Conventionally, the exposure of the resist layer and the exposure of the solder resist layer, as described above, have been performed by placing mask films in close contact with the resist layer and the solder resist layer, respectively. The mask films have openings that have the same shape as a circuit pattern or a pattern (hereinafter, referred to as a circuit pattern or the like). In the pattern, the periphery of the upper surface of an electrode portion is coated to form a predetermined width of coating. However, if the exposure apparatus disclosed in Japanese Unexamined Patent Publication No. 2004-1244 is used, it is possible to directly perform exposure on the resist layer and the solder resist layer to form patterns.

However, when printed circuit boards are produced as described above, oxygen in the compositions of the resist layer and the solder resist layer decreases immediately after the lamination process, thereby radical reaction becoming more active. Therefore, the sensitivities of the resist layers are at high levels. Hence, if exposure is performed immediately after the lamination process, the line width of a pattern becomes thick, and the resolution of the pattern becomes lower. Further, if the development process and the etching process are performed after the exposure process is performed in such a state, the line width of a pattern after development becomes thick. Hence, when the pattern has a narrow L & S (line and space), there is a risk that adjacent lines are short-circuited.

Further, if a printed circuit boards is kept for long time after the lamination process, chemical reaction between the conductive layer and the resist progresses, and a so-called “change-to-red” failure is induced. Consequently, in the later etching process, a problem that etching is delayed or a problem that etching is not performed occurs. Further, the resist layer is exposed to ambient light, such as safe light, and the resist layer becomes sensitive to light. Therefore, if exposure is performed in this state, there is a problem that the line width of the pattern becomes thick in a manner similar to the case in which exposure is performed immediately after the lamination process.

Further, photopolymerization of the resist layer does not sufficiently proceeds immediately after the exposure process. Therefore, if development is performed immediately after the exposure, the line width of the pattern becomes thin. If the development process and the etching process are performed in such a state, there are problems that the resistance and impedance of the produced printed circuit board become large and that the lines are disconnected.

Further, if the printed circuit board is kept for long time after the exposure process, the degree of photopolymerization exceeds a required level. Therefore, the line width of the pattern becomes thick. Hence, if the development process and the etching process are performed in such a state, there is a problem that the line width of the pattern becomes thick in a manner similar to the case in which exposure is performed immediately after the lamination process.

The aforementioned problems arise not only when exposure and development are performed on the resist layer but also when exposure and development are performed on the solder resist layer.

### DISCLOSURE OF INVENTION

In view of the foregoing circumstances, it is an object of the present invention to produce printed circuit boards in which patterns of uniform line width are formed.

A first method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:

exposing a predetermined area of the photosensitive layer to light carrying lamination date/time information, the information representing date/time when the lamination step was performed;

judging, by reading out the lamination date/time information, whether passage time after the date/time when the lamination step was performed, the date/time being represented by the read lamination date/time information, is within the range of predetermined hold time; and

controlling the exposure step so that the exposure step is performed only if the judgment is YES.

The “lamination date/time information” may be any kind of information as long as date/time when the lamination step was performed can be identified. For example, a numerical value, such as “2004.10.23”, representing the date/time itself of the lamination step, a barcode or sign representing the date/time of the lamination step or the like may be used.

The “predetermined hold time” means time that makes obtainment a circuit pattern having a desirable line width possible if exposure, development and etching are performed in standard conditions within the range of the hold time.

In the first method for producing a printed circuit board according to the present invention, the step of controlling may be a step of issuing a predetermined warning if the judgment is NO.

As the “predetermined warning”, an arbitrary method for notifying an operator who is controlling the production process of printed circuit boards may be used. For example, a warning by voice, a warning by ON/OFF of a lamp, a warning by display on a monitor or the like may be used.

In the first method for producing a printed circuit board according to the present invention, the step of controlling may be a step of stopping conveyance of the substrate to the exposure step if the judgment is NO.

A second method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:

exposing a predetermined area of the photosensitive layer to light carrying exposure date/time information, the information representing date/time when the exposure step was performed;

judging, by reading out the exposure date/time information, whether passage time after the date/time when the exposure step was performed, the date/time being represented by the read exposure date/time information, is within the range of predetermined hold time; and

controlling the development step so that the development step is performed only if the judgment is YES.

The “exposure date/time information” may be any kind of information as long as date/time when the exposure step was performed can be identified. For example, a numerical value, such as “2004.10.23”, representing the date/time itself of the exposure step, a barcode or sign representing the date/time of the exposure step or the like may be used.

The exposure of the exposure date/time information may be performed at the same as the exposure in the exposure step. Alternatively, the exposure of the exposure date/time information may be performed before the development step.

In the second method for producing a printed circuit board according to the present invention, the step of controlling may be a step of issuing a predetermined warning if the judgment is NO.

In the second method for producing a printed circuit board according to the present invention, the step of controlling may be a step of stopping conveyance of the substrate to the exposure step if the judgment is NO.

A third method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:

exposing a predetermined area of the photosensitive layer to light carrying lamination date/time information, the information representing date/time when the lamination step was performed;

obtaining, by reading out the lamination date/time information, passage time from the date/time when the lamination step was performed, the date/time being represented by the read lamination date/time information, to the start of the exposure step; and

setting, based on the length of the passage time, an exposure condition in the exposure step.

A fourth method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:

exposing a predetermined area of the photosensitive layer to light carrying lamination date/time information, the information representing date/time when the lamination step was performed;

obtaining, by reading out the lamination date/time information, passage time from the date/time when the lamination step was performed, the date/time being represented by the read lamination date/time information, to the start of the exposure step; and

setting, based on the length of the passage time, a development condition in the development step.

A fifth method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern, a development step for developing the photosensitive layer that has been exposed to light in the pattern and an etching step for forming a circuit pattern including the predetermined pattern by etching the conductive layer on the substrate after the development, the method characterized by comprising the steps of:

exposing a predetermined area of the photosensitive layer to light carrying lamination date/time information, the information representing date/time when the lamination step was performed;

obtaining, by reading out the lamination date/time information, passage time from the date/time when the lamination step was performed, the date/time being represented by the read lamination date/time information, to the start of the exposure step; and

setting, based on the length of the passage time, an etching condition in the etching step.

A sixth method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:

exposing a predetermined area of the photosensitive layer to light carrying exposure date/time information, the information representing date/time when the exposure step was performed;

obtaining, by reading out the exposure date/time information, passage time from the date/time when the exposure step was performed, the date/time being represented by the read exposure date/time information, to the start of the development step; and

setting, based on the length of the passage time, a development condition in the development step.

A seventh method for producing a printed circuit board according to the present invention is a method for producing a printed circuit board, the method comprising a lamination step for superposing a photosensitive layer on a conductive layer on a substrate, an exposure step for exposing the photosensitive layer to light in a predetermined pattern, a development step for developing the photosensitive layer that has been exposed to light in the pattern and an etching step for forming a circuit pattern including the predetermined pattern by etching the conductive layer on the substrate after the development, the method characterized by comprising the steps of:

exposing a predetermined area of the photosensitive layer to light carrying exposure date/time information, the information representing date/time when the exposure step was performed;

obtaining, by reading out the exposure date/time information, passage time from the date/time when the exposure step was performed, the date/time being represented by the read exposure date/time information, to the start of the development step; and

setting, based on the length of the passage time, an etching condition in the etching step.

In the sixth and seventh methods for producing a printed circuit board according to the present invention, the exposure of the exposure date/time information may be performed at the same as the exposure in the exposure step. Alternatively, the exposure of the exposure date/time information may be performed before the development step.

A first apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the lamination means includes a means for exposing a predetermined area of the photosensitive layer to light carrying lamination date/time information, the information representing date/time when the lamination was performed, and wherein the exposure means includes a means for judging, by reading out the lamination date/time information, whether passage time after the date/time when the lamination was performed, the date/time being represented by the read lamination date/time information, is within the range of predetermined hold time and a means for controlling the exposure means so that the exposure means performs the exposure only if the judgment is YES.

In the first apparatus for producing a printed circuit board according to the present invention, the means for controlling may include a means for issuing a predetermined warning if the judgment is NO.

Further, in the first apparatus for producing a printed circuit board according to the present invention, the means for controlling may include a means for stopping conveyance of the substrate to the exposure means if the judgment is NO.

A second apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the exposure means includes a means for exposing a predetermined area of the photosensitive layer to light carrying exposure date/time information, the information representing date/time when the exposure was performed, and wherein the development means includes a means for judging, by reading out the exposure date/time information, whether passage time after the date/time when the exposure was performed, the date/time being represented by the read exposure date/time information, is within the range of predetermined hold time and a means for controlling the development means so that the development means performs the development only if the judgment is YES.

In the second apparatus for producing a printed circuit board according to the present invention, the means for controlling may include a means for issuing a predetermined warning if the judgment is NO.

In the second apparatus for producing a printed circuit board according to the present invention, the means for controlling may include a means for stopping conveyance of the substrate to the development means if the judgment is NO.

A third apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the lamination means includes a means for exposing a predetermined area of the photosensitive layer to light carrying lamination date/time information, the information representing date/time when the lamination was performed, and wherein the exposure means includes a means for obtaining, by reading out the lamination date/time information, passage time from the date/time when the lamination was performed, the date/time being represented by the read lamination date/time information, to the start of the exposure and a means for setting, based on the length of the passage time, an exposure condition at the exposure means.

A fourth apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the lamination means includes a means for exposing a predetermined area of the photosensitive layer to light carrying lamination date/time information, the information representing date/time when the lamination was performed, and wherein the exposure means includes a means for obtaining, by reading out the lamination date/time information, passage time from the date/time when the lamination was performed, the date/time being represented by the read lamination date/time information, to the start of the exposure, and wherein the development means includes a means for setting, based on the length of the passage time, a development condition at the development means.

A fifth apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern, a development means for developing the photosensitive layer that has been exposed to light in the pattern and an etching means for forming a circuit pattern including the predetermined pattern by etching the conductive layer on the substrate after the development, the apparatus characterized in that the lamination means includes a means for exposing a predetermined area of the photosensitive layer to light carrying lamination date/time information, the information representing date/time when the lamination was performed, and wherein the exposure means includes a means for obtaining, by reading out the lamination date/time information, passage time from the date/time when the lamination was performed, the date/time being represented by the read lamination date/time information, to the start of the exposure, and wherein the etching means includes a means for setting, based on the length of the passage time, an etching condition at the etching means.

A sixth apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the exposure means includes a means for exposing a predetermined area of the photosensitive layer to light carrying exposure date/time information, the information representing date/time when the exposure was performed, and wherein the development means includes a means for obtaining, by reading out the exposure date/time information, passage time from the date/time when the exposure was performed, the date/time being represented by the read exposure date/time information, to the start of the development and a means for setting, based on the length of the passage time, a development condition at the development means.

A seventh apparatus for producing a printed circuit board according to the present invention is an apparatus for producing a printed circuit board, the apparatus comprising a lamination means for superposing a photosensitive layer on a conductive layer on a substrate, an exposure means for exposing the photosensitive layer to light in a predetermined pattern, a development means for developing the photosensitive layer that has been exposed to light in the pattern and an etching means for forming a circuit pattern including the predetermined pattern by etching the conductive layer on the substrate after the development, the apparatus characterized in that the exposure means includes a means for exposing a predetermined area of the photosensitive layer to light carrying exposure date/time information, the information representing date/time when the exposure was performed, and wherein the development means includes a means for obtaining, by reading out the exposure date/time information, passage time from the date/time when the exposure was performed, the date/time being represented by the read exposure date/time information, to the start of the development, and wherein the etching means includes a means for setting, based on the length of the passage time, an etching condition at the etching means.

In the first method and apparatus for producing a printed circuit board according to the present invention, a predetermined area of a photosensitive layer is exposed to light carrying lamination date/time information. Next, the lamination date/time information is read out and judgment is made as to whether passage time after date/time when the lamination step was performed, the date/time being represented by the read lamination date/time information, is within the range of predetermined hold time. Then, the exposure step is controlled so that the exposure step is performed only if the judgment is YES. Therefore, it is possible to perform desirable exposure on the photosensitive layer. Consequently, it is possible to form patterns of uniform line width on substrates.

In the second method and apparatus for producing a printed circuit board according to the present invention, a predetermined area of a photosensitive layer is exposed to light carrying exposure date/time information. Next, the exposure date/time information is read out, and judgment is made as to whether passage time after date/time when the exposure step was performed, the date/time being represented by the read exposure date/time information, is within the range of predetermined hold time. Then, the development step is controlled so that the development step is performed only if the judgment is YES. Therefore, it is possible to perform desirable development on the photosensitive layer. Consequently, it is possible to form patterns of uniform line width on substrates.

In the third method and apparatus for producing a printed circuit board according to the present invention, a predetermined area of a photosensitive layer is exposed to light carrying lamination date/time information. Next, the lamination date/time information is read out, and passage time from date/time when the lamination step was performed, the date/time being represented by the read lamination date/time information, to the start of the exposure step is obtained. Then, an exposure condition in the exposure step is set based on the length of the passage time. Therefore, it is possible to perform desirable development on the photosensitive layer. Consequently, it is possible to form patterns of uniform line width on substrates.

In the fourth method and apparatus for producing a printed circuit board according to the present invention, a predetermined area of a photosensitive layer is exposed to light carrying lamination date/time information. Next, the lamination date/time information is read out, and passage time from date/time when the lamination step was performed, the date/time being represented by the read lamination date/time information, to the start of the exposure step is obtained. Then, a development condition in the development step is set based on the length of the passage time. Therefore, it is possible to perform desirable development on the photosensitive layer. Consequently, it is possible to form patterns of uniform line width on substrates.

In the fifth method and apparatus for producing a printed circuit board according to the present invention, a predetermined area of the photosensitive layer is exposed to light carrying lamination date/time information. Next, the lamination date/time information is read out, and passage time from date/time when the lamination step was performed, the date/time being represented by the read lamination date/time information, to the start of the exposure step is obtained. Then, an etching condition in the etching step is set based on the length of the passage time. Therefore, it is possible to perform desirable etching on the photosensitive layer. Consequently, it is possible to form patterns of uniform line width on substrates.

In the sixth method and apparatus for producing a printed circuit board according to the present invention, a predetermined area of the photosensitive layer is exposed to light carrying exposure date/time information. Next, the exposure date/time information is read out, and passage time from date/time when the exposure step was performed, the date/time being represented by the read exposure date/time information, to the start of the development step is obtained. Then, a development condition in the development step is set based on the length of the passage time. Therefore, it is possible to perform desirable development on the photosensitive layer. Consequently, it is possible to form patterns of uniform line width on substrates.

In the seventh method and apparatus for producing a printed circuit board according to the present invention, a predetermined area of the photosensitive layer is exposed to light carrying exposure date/time information. Next, the exposure date/time information is read out, and passage time from date/time when the exposure step was performed, the date/time being represented by the read exposure date/time information, to the start of the development step is obtained. Then, an etching condition in the etching step is set based on the length of the passage time. Therefore, it is possible to perform desirable etching on the photosensitive layer. Consequently, it is possible to form patterns of uniform line width on substrates.

### BRIEF DESCRIPTION OF DRAWINGS

FIG. 1 is a schematic block diagram illustrating the configuration of a system for producing a printed circuit board according to the first embodiment of the present invention;

FIG. 2 is a schematic block diagram illustrating the configuration of a lamination apparatus according to the first embodiment;

FIG. 3 is a diagram illustrating an example of a laser exposure apparatus;

FIG. 4 is a schematic block diagram illustrating the configuration of an exposure apparatus according to the first embodiment;

FIG. 5 is a schematic block diagram illustrating the configuration of a development apparatus according to the first embodiment;

FIG. 6 is a schematic block diagram illustrating the configuration of an etching apparatus according to the first embodiment;

FIG. 7 is a flowchart illustrating the process performed in the first embodiment;

FIG. 8 is a schematic block diagram illustrating the configuration of a system for producing a printed circuit board according to the second embodiment;

FIG. 9 is a schematic block diagram illustrating the configuration of an exposure apparatus according to the second embodiment;

FIG. 10 is a diagram illustrating the relationship between passage time after a lamination step and the line width of a circuit pattern;

FIG. 11 is a diagram illustrating the relationship between exposure energy at the time of exposure and the line width of a circuit pattern;

FIG. 12 is a schematic block diagram illustrating the configuration of a system for producing a printed circuit board according to the third embodiment;

FIG. 13 is a schematic block diagram illustrating the configuration of a development apparatus according to the third embodiment;

FIG. 14 is a diagram illustrating the relationship between exposure time and the line width of a circuit pattern;

FIG. 15 is a diagram illustrating the relationship between the temperature of developer and the line width of a circuit pattern;

FIG. 16 is a diagram illustrating the relationship between shower pressure when developer is sprayed on a substrate and the line width of a circuit pattern;

FIG. 17 is a diagram illustrating the relationship between the flow amount of developer and the line width of a circuit pattern;

FIG. 18 is a schematic block diagram illustrating the configuration of a system for producing a printed circuit board according to the fourth embodiment;

FIG. 19 is a schematic block diagram illustrating the configuration of an etching apparatus according to the fourth embodiment;

FIG. 20 is a diagram illustrating the relationship between etching time and the line width of a circuit pattern;

FIG. 21 is a diagram illustrating the relationship between the temperature of etchant and the line width of a circuit pattern;

FIG. 22 is a diagram illustrating the relationship between shower pressure when etchant is sprayed on substrate K and the line width of a circuit pattern;

FIG. 23 is a diagram illustrating the relationship between the flow amount of etchant and the line width of a circuit pattern;

FIG. 24 is a schematic block diagram illustrating the configuration of a system for producing a printed circuit board according to the fifth embodiment;

FIG. 25 is a schematic block diagram illustrating the configuration of a development apparatus according to the fifth embodiment;

FIG. 26 is a diagram illustrating the relationship between passage time after an exposure step and the line width of a circuit pattern;

FIG. 27 is a schematic block diagram illustrating the configuration of a system for producing a printed circuit board according to the sixth embodiment;

FIG. 28 is a schematic block diagram illustrating the configuration of an etching apparatus according to the sixth embodiment;

FIG. 29 is a diagram illustrating placement of a substrate removal unit according to the seventh embodiment;

FIG. 30 is a diagram illustrating the configuration of the substrate removal unit, viewed from the upstream side of a conveyance direction illustrated in FIG. 29; and

FIGS. 31A through 31F are diagrams illustrating the operations of the substrate removal unit.

### BEST MODE FOR CARRYING OUT THE INVENTION

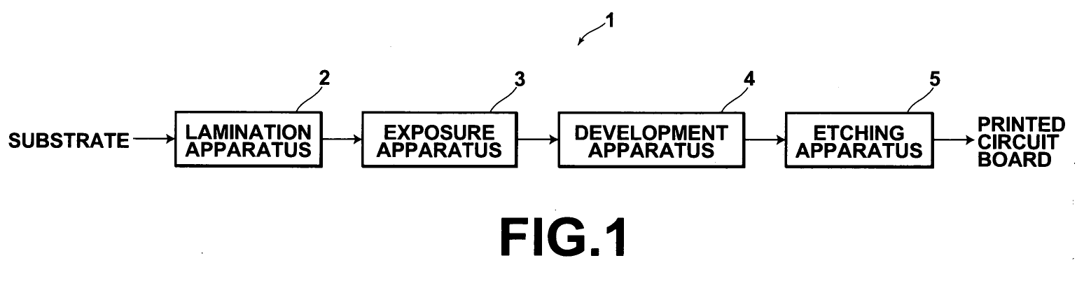

Hereinafter, embodiments of the present invention will be described with reference to the drawings. FIG. 1 is a schematic block diagram illustrating the configuration of a system for producing a printed circuit board according to the first embodiment of the present invention. As illustrated in FIG. 1, a system 1 for producing a printed circuit board according to the present embodiment includes a lamination apparatus 2, an exposure apparatus 3, a development apparatus 4 and an etching apparatus 5. The lamination apparatus 2 forms a resist layer by superposing a dry film resist (DFR) on substrate K that has been coated with a copper film. The exposure apparatus 3 exposes the resist layer to light in a pattern that has the same shape as that of a circuit pattern. The development apparatus 4 forms a resist pattern that has the same shape as that of the circuit pattern by developing the resist layer that has been exposed to light. The etching apparatus 5 forms a circuit pattern by etching the copper film on the substrate K, on which the resist pattern has been formed.

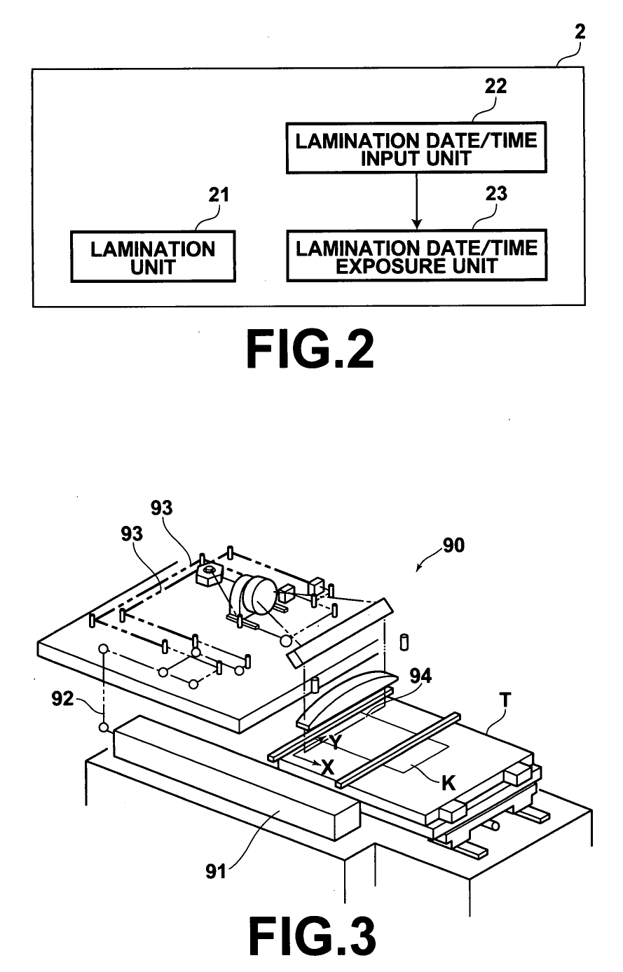

FIG. 2 is a schematic block diagram illustrating the configuration of the lamination apparatus 2 according to the first embodiment. As illustrated in FIG. 2, the lamination apparatus 2 includes a lamination unit 21, a lamination date/time input unit 22 and a lamination date/time exposure unit 23. The lamination unit 21 superposes a DFR on substrate K. The lamination date/time input unit 22 inputs lamination date/time. The lamination date/time exposure unit 23 exposes a resist layer formed on substrate K to light carrying lamination date/time information, representing lamination date/time.

The lamination date/time input unit 22 includes a clock. When the lamination date/time exposure unit 23 performs lamination date/time exposure, the lamination date/time input unit 22 inputs lamination date/time information representing the current date/time to the lamination date/time exposure unit 23. Here, the lamination date/time information may be a numerical value, such as “2004.10.29.11:40”, representing lamination date/time itself, a barcode representing the lamination date/time or some kind of sign representing the lamination date/time. The lamination date/time input unit 22 inputs binary lamination date/time information pattern data to the lamination date/time exposure unit 23. The binary lamination date/time information pattern data is data representing lamination date/time, a barcode or a sign.

Here, since the resist layer is also exposed to light carrying exposure date/time information, as will be described later, it is desirable that the lamination date/time information includes a character, such as “L” for example, and that the exposure date/time information includes a character, such as “E” for example, so that the lamination date/time information and the exposure date/time information can be distinguished from each other.

As the lamination date/time exposure unit 23, a laser exposure apparatus is used. The laser exposure apparatus uses laser light or the like, and directly exposes the resist layer to light carrying lamination date/time information. FIG. 3 is a diagram illustrating an example of the laser exposure apparatus. As illustrated in FIG. 3, a laser exposure apparatus 90 is structured so that laser light 92 emitted from a laser light source 91 is divided into a plurality of beams 93 by a beam splitter or a beam separator. Further, the divided beams become beams 94 for exposure that are aligned in a row and reach table T for conveying substrate K. Substrate K placed on the table T is scanned with the beams 94 in a main scan direction (Y direction). Further, table T is moved in a sub-scan direction (X direction). Accordingly, the resist layer is exposed to light carrying the lamination date/time information.

The color of a resist layer changes by exposing the resist layer to light. Therefore, the color of the exposed portion of the resist layer changes. For example, if the color of the resist layer is navy blue, the color of the exposed portion of the resist layer becomes dark navy blue. Therefore, if substrate K after exposure is observed, it is possible to visually recognize that the substrate K has been exposed to light carrying lamination date/time information. Here, the substrate K is exposed to light carrying the lamination date/time information so that an area of the substrate K, the area being exposed to the light carrying the lamination date/time information, does not overlap with an area of the substrate K, the area being exposed to light forming a pattern by the exposure apparatus 3.

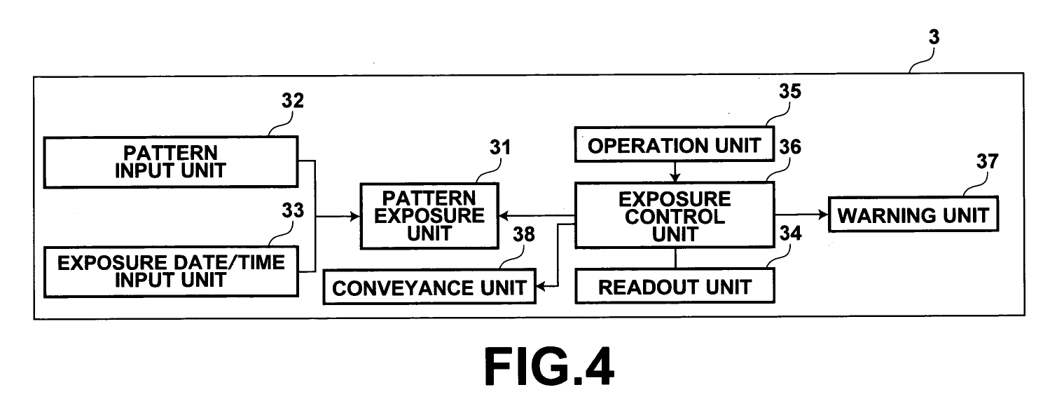

FIG. 4 is a schematic block diagram illustrating the configuration of the exposure apparatus 3 according to the first embodiment. As illustrated in FIG. 4, the exposure apparatus 3 includes a pattern exposure unit 31, a pattern input unit 32, an exposure date/time input unit 33, a readout unit 34, an operation unit 35, an exposure control unit 36 and a warning unit 37. The pattern exposure unit 31 exposes the substrate K to light forming a pattern that has the same shape as that of a circuit pattern and to light carrying exposure date/time information representing exposure date/time. The pattern input unit 32 inputs binary pattern data representing a pattern to be formed by exposure to the pattern exposure unit 31. The exposure date/time input unit 33 inputs binary exposure date/time pattern data representing exposure date/time to the pattern exposure unit 31. The readout unit 34 reads out lamination date/time information present on the substrate K. The operation unit 35 is used by an operator to operate the exposure apparatus 3. The exposure control unit 36 controls drive of the exposure apparatus 3. The warning unit 37 will be described later. Further, the exposure apparatus 3 includes a conveyance unit 38 for conveying the substrate K to the pattern exposure unit 31 through the readout unit 34 by placing the substrate K on a table.

The pattern exposure unit 31 includes a laser exposure apparatus similar to the one used in the lamination apparatus 2. The pattern exposure unit 31 exposes the resist layer, based on pattern data input by the pattern input unit 32 and the exposure date information pattern data input by the exposure date/time input unit 33, to light forming a pattern that has the same shape as that of a circuit pattern and to light carrying exposure date information.

The exposure date/time input unit 33 includes a clock. When the pattern exposure unit 31 exposes the resist layer to light forming a pattern, the exposure date/time input unit 33 inputs binary exposure date/time pattern data representing exposure date/time information, which represents the current date/time, to the pattern exposure unit 31. Here, the exposure date information may be a numerical value, such as “2004.10.29.11:40”, representing exposure date/time itself, a barcode representing the exposure date/time or some kind of sign representing the exposure date/time, which are similar to the lamination date/time information.

The readout unit 34 includes a CCD for reading out the lamination date/time information present on the substrate K and an A/D converter. The A/D converter converts analog signals output from the CCD into digital signals (hereinafter, referred to as lamination date/time signals) representing the lamination date/time information. The readout unit 34 is provided at a position on the most upstream side of the conveyance path of the substrate K.

The operation unit 35 includes an input unit, such as a keyboard or a touch panel, for performing various kinds of input. The operation unit 35 also includes a monitor for displaying various kinds of information to control the exposure apparatus 3. The operation unit 35 receives inputs by an operator and instructs the exposure control unit 36 based on the inputs by the operator. Further, since the state of exposure is displayed on the monitor, the operator can check the current state of exposure.

The exposure control unit 36 judges lamination date/time based on a lamination date/time signal output by the readout unit 34. Specifically, the exposure control unit 36 judges the lamination date/time by performing image analysis on an image of the lamination date/time information represented by the lamination date/time signal and by obtaining a number, a barcode or a sign representing the lamination date/time. Further, the exposure control unit 36 includes a clock and obtains passage time PT0 from the lamination date/time to the current date/time.

Here, when a printed circuit board is produced, oxygen in the composition of the resist layer decreases immediately after the lamination step, thereby radical reaction becoming more active. Therefore, the sensitivity of the resist layer is at a high level. Hence, if exposure is performed immediately after the lamination step, the line width of a circuit pattern becomes thick, and the resolution of the circuit pattern becomes lower. Further, if the development step and the etching step are performed after the exposure step is performed in such a state, the line width of a pattern after development becomes thick. Hence, when the pattern has a narrow L & S (line and space), there is a risk that adjacent lines are short-circuited.

Further, if the printed circuit board is kept for long time after the lamination step, chemical reaction between the conductive layer and the resist layer progresses, and a so-called “change-to-red” failure is induced. Consequently, in the later etching step, a problem that etching is delayed or a problem that etching is not performed occurs. Further, the resist layer is exposed to ambient light, such as safe light, and the resist layer becomes sensitive to light. Therefore, if exposure is performed in this state, there is a problem that the line width of a circuit pattern becomes thick in a manner similar to the case in which exposure is performed immediately after the lamination process.

Therefore, the exposure control unit 36 judges whether passage time PT0 is within the range of predetermined hold time HT0 If the passage time PT0 is not within the range of the hold time HT0, the exposure control unit 36 outputs a warning signal to the warning unit 37.

If the passage time PT0 is within the range of the hold time HT0, the exposure control unit 36 controls drive of the pattern exposure unit 31 and the conveyance unit 38 so that the set substrate K is exposed to light.

The warning unit 37 includes a warning lamp. When the warning unit 37 receives a warning signal, the warning unit 37 notifies the operator, by turning on and off the warning lamp, that time passed after the lamination step was performed on the substrate K is not within the range of the hold time. The warning unit 37 may notifies the operator using voice instead of the warning lamp.

If the warning unit 37 issues warning, the operator can stop drive of the exposure apparatus 3 and remove the substrate K from the exposure apparatus 3 so that an exposure operation that the exposure apparatus 3 is going to perform on the substrate K is stopped.

The exposure control unit 36 may notify the operator that time passed after the lamination step was performed on the substrate K is not within the range of the hold time by outputting a warning signal to the operation unit 35 and by displaying the information that the time is not within the range of the hold time on a monitor of the operation unit 35.

Further, the exposure control unit 36 may output different warning signals depending on whether the passage time PT0 has exceeded the hold time HT0 or not. When the exposure control unit 36 outputs such different signals, the warning unit 37 may include warning lamps that have different colors, for example. Then, different warning lamps may be turned on and off depending on whether the passage time PT0 has exceeded the hold time HT0 or not. Alternatively, the notification may be made by using different voices depending on whether the passage time PT0 has exceeded the hold time HT0 or not. Further, when the warning signal is output to the operation unit 35, different information may be displayed on the monitor of the operation unit 35 depending on whether the passage time PT0 has exceeded the hold time HT0 or not.

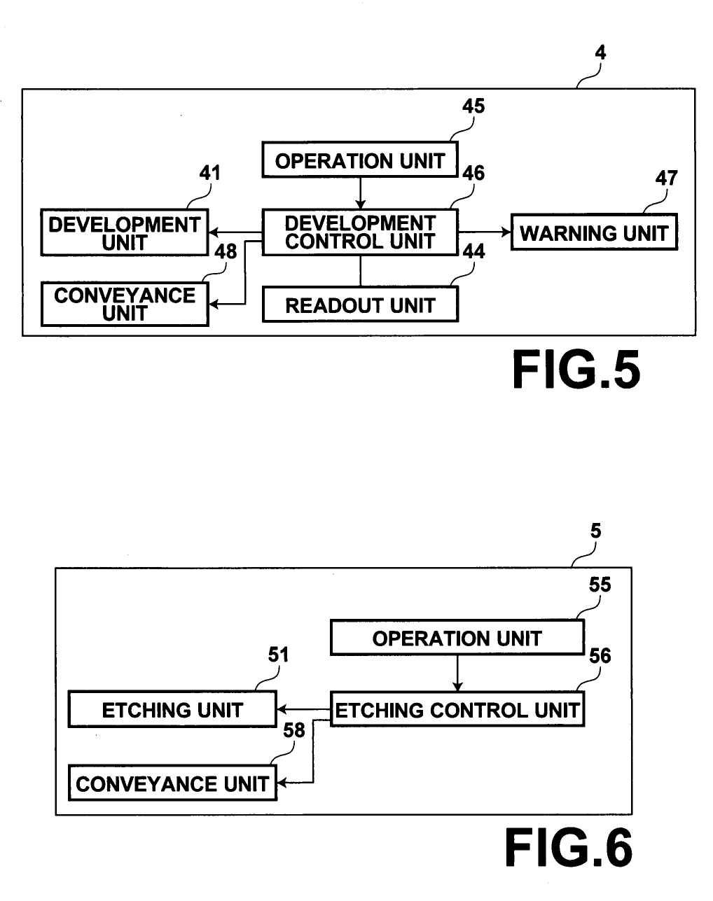

FIG. 5 is a schematic block diagram illustrating the configuration of a development apparatus 4 according to the first embodiment. As illustrated in FIG. 5, the development unit 4 includes a development unit 41, a readout unit 44, an operation unit 45, a development control unit 46 and a warning unit 47. The development unit 41 develops substrate K that has been exposed to light. The readout unit 44 reads out exposure date/time information present on the substrate K. The operation unit 45 is used by the operator to operate the development apparatus 4. The development control unit 46 controls drive of the development apparatus 4. The warning unit 47 will be described later. Further, the development apparatus 4 includes a conveyance unit 48 for conveying the substrate K.

The development unit 41 includes a spraying apparatus and a temperature adjustment apparatus. The spraying apparatus sprays developer on the substrate K, and the temperature adjustment apparatus adjusts the temperature of the developer. The development unit 41 performs development for a predetermined time period by spraying the developer on the substrate K at a predetermined temperature and at a predetermined shower pressure.

The readout unit 44 includes a CCD for reading out the exposure date/time information on the substrate K and an A/D converter. The A/D converter converts analog signals output from the CCD into digital signals (hereinafter, referred to as exposure date/time signals) representing the exposure date/time information. The readout unit 44 is provided at a position on the most upstream side of the conveyance path of the substrate K.

The operation unit 45 includes an input unit, such as a keyboard or a touch panel, for performing various kinds of input. The operation unit 45 also includes a monitor for displaying various kinds of information to control the development apparatus 4. The operation unit 45 receives inputs by an operator and instructs the development control unit 46 based on the inputs by the operator. Further, since the state of development is displayed on the monitor, the operator can check the current state of development.

The development control unit 46 judges exposure date/time based on the exposure date/time signal output by the readout unit 44. Specifically, the development control unit 46 judges the exposure date/time by performing image analysis on an image of the exposure date/time information represented by the exposure date/time signal and by obtaining a number, a barcode or a sign representing the exposure date/time. Further, the development control unit 46 includes a clock and obtains passage time PT1 from the exposure date/time to the current date/time.

Here, when a printed circuit board is produced, photopolymerization of the resist layer does not sufficiently proceed immediately after the exposure step. Therefore, if development is performed immediately after the exposure, the line width of the circuit pattern becomes thin. If the development step and the etching step are performed in such a state, there are problems that the resistance and impedance of the produced printed circuit board becomes large and that the circuit is disconnected.

Further, if the printed circuit board is kept for long time after the exposure step, the degree of photopolymerization exceeds a required level. Therefore, the line width of the circuit pattern becomes thick. Hence, if the development step and the etching step are performed in such a state, there is a problem that the line width of the circuit pattern becomes thick in a manner similar to the case in which exposure is performed immediately after the lamination step.

Therefore, the development control unit 46 judges whether the passage time PT1 is within the range of predetermined hold time HT1. If the passage time PT1 is not within the range of the hold time HT1, the development control unit 46 outputs a warning signal to the warning unit 47.

If the passage time PT1 is within the range of the hold time HT1, the development control unit 46 controls drive of the development unit 41 and the conveyance unit 48 so that the set substrate K is developed.

The development control unit 46 controls drive of the development unit 41 and the conveyance unit 48 so that development time (in other words, conveyance speed of the substrate K), the temperature of the developer, shower pressure at the time when the developer is sprayed and the flow amount of the developer become predetermined values.

The warning unit 47 includes a warning lamp. When the warning unit 47 receives a warning signal, the warning unit 47 notifies the operator, by turning on and off the warning lamp, that time passed after the exposure step was performed on the substrate K is not within the range of the hold time. The warning unit 47 may notifies the operator using voice instead of the warning lamp.

If the warning unit 47 issues warning, the operator can stop drive of the development apparatus 4 and remove the substrate K from the development apparatus 4 so that a development operation that the development apparatus 4 is going to perform on the substrate K is stopped.

The development control unit 46 may notify the operator that time passed after the exposure step was performed on the substrate K is not within the range of the hold time by outputting a warning signal to the operation unit 45 and by displaying the information that the time is not within the range of the hold time on a monitor of the operation unit 45.

Further, the development control unit 46 may output different warning signals depending on whether the passage time PT1 has exceeded the hold time HT1 or not. When the development control unit 46 outputs such different warning signals, the warning unit 47 may include warning lamps that have different colors, for example. Then, different warning lamps may be turned on and off depending on whether the passage time PT1 has exceeded the hold time HT1 or not. Alternatively, the notification may be made by using different voices depending on whether the passage time PT1 has exceeded the hold time HT1 or not. Further, when the warning signal is output to the operation unit 45, different information may be displayed on the monitor of the operation unit 45 depending on whether the passage time PT1 has exceeded the hold time HT1 or not.

FIG. 6 is a schematic block diagram illustrating the configuration of an etching apparatus 5 according to the first embodiment. As illustrated in FIG. 6, the etching apparatus 5 includes an etching unit 51, an operation unit 55 and an etching control unit 56. The etching unit 51 performs etching on substrate K that has been developed. The operation unit 55 is used by the operator to operate the etching apparatus 5. The etching control unit 56 controls drive of the etching apparatus 5. Further, the etching apparatus 5 includes a conveyance unit 58 for conveying the substrate K.

The etching unit 51 includes a spraying apparatus and a temperature adjustment apparatus. The spraying apparatus sprays etchant on the substrate K, and the temperature adjustment apparatus adjusts the temperature of the etchant. The etching unit 51 performs etching for a predetermined time period by spraying the etchant on the substrate K at a predetermined temperature and at a predetermined shower pressure.

The operation unit 55 includes an input unit, such as a keyboard or a touch panel, for performing various kinds of input. The operation unit 55 also includes a monitor for displaying various kinds of information to control the etching apparatus 5. The operation unit 55 receives inputs by an operator and instructs the etching control unit 56 based on the inputs by the operator. Further, since the state of etching is displayed on the monitor, the operator can check the current state of etching.

The etching control unit 56 controls drive of the etching unit 51 and the conveyance unit 58 so that etching time (in other words, conveyance speed of the substrate K), the temperature of the etchant, shower pressure at the time when the etchant is sprayed and the flow amount of the etchant become predetermined values.

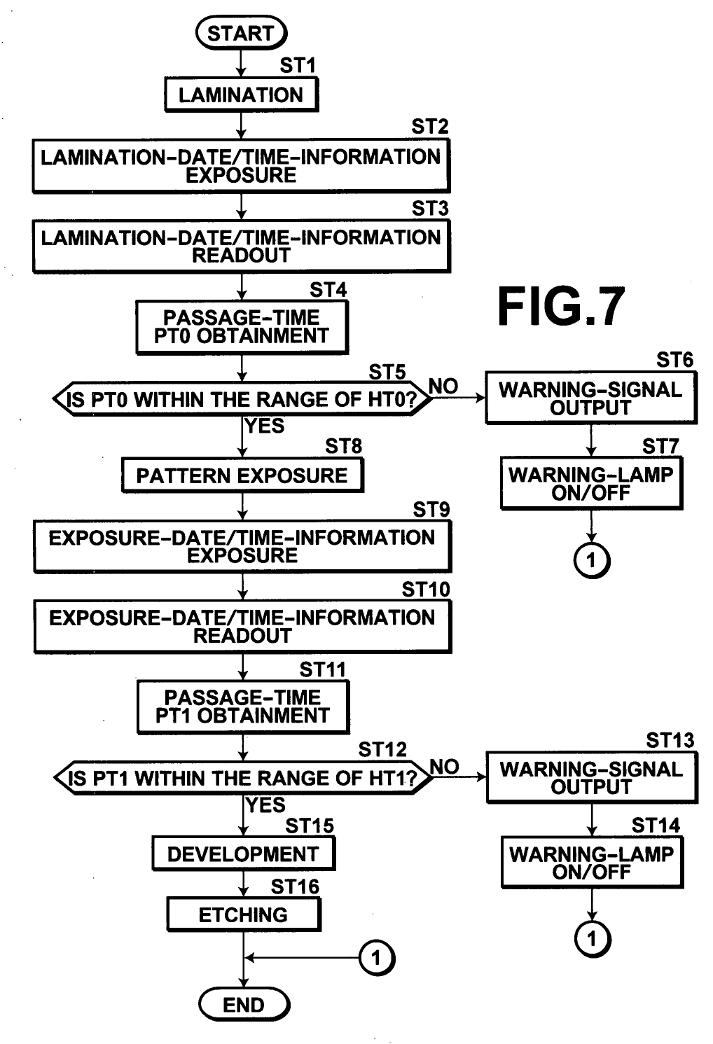

FIG. 7 is a flowchart illustrating the process performed in the first embodiment. First, the lamination apparatus 2 superposes DFR on the substrate K to form a resist layer (step ST1). Further, the resist layer is exposed to light carrying lamination date information (step ST2).

Next, an operator sets the substrate K on which the resist layer has been formed in the exposure apparatus 3 and drives the exposure apparatus 3. Then, the exposure apparatus 3 reads out the lamination date/time information (step ST3). Accordingly, passage time PT0 from lamination date/time represented by the lamination date/time information to the current date/time is obtained (step ST4). Then, judgment is made as to whether the passage time PT0 is within the range of predetermined hold time HT0 (step ST5). If the passage time PT0 is not within the range of the hold time HT0 (if the judgment in step ST5 is NO), a warning signal is output to the warning unit 37 (step ST6). The warning unit 37 turns on and off a warning lamp (step ST7), and processing ends. Accordingly, the operator can stop drive of the exposure apparatus 3 and remove the substrate K from the exposure apparatus 3 so that an exposure operation that the exposure apparatus 3 is going to perform on the substrate K is stopped.

In contrast, if the judgment in step ST5 is YES, the exposure apparatus 3 exposes the substrate K to light forming a pattern that has the same shape as that of a circuit pattern (step ST8). Further, the exposure apparatus 3 exposes the substrate K to light carrying exposure date/time information (step ST9), and the exposure step ends.

Next, the operator sets the substrate K that has been exposed to light in the development apparatus 4 and drives the development apparatus 4. Then, the development apparatus 4 reads out the exposure date/time information (step ST10), and obtains passage time PT1 from exposure date/time represented by the exposure date/time information to the current date/time (step ST11). Then, judgment is made as to whether the passage time PT1 is within the range of predetermined hold time HT1 (step ST12). If the passage time PT1 is not within the range of the predetermined hold time HT1 (if the judgment in step ST12 is NO), a warning signal is output to the warning unit 47 (step ST13). The warning unit 47 turns on and off a warning lamp (step ST14), and processing ends. Accordingly, the operator can stop drive of the development apparatus 4 and remove the substrate K from the development apparatus 4 so that a development operation that the development apparatus 4 is going to perform on the substrate K is stopped.

In contrast, if the judgment in step ST12 is YES, the development apparatus 4 develops the substrate K (step ST15), and the development step ends.

Then, the etching apparatus 5 performs etching on the substrate K that has been developed (step ST16). Accordingly, a printed circuit board is completed and processing ends.

As described above, in the first embodiment, judgment is made as to whether passage time PT0 from the lamination date/time to the start of the exposure step is within the range of hold time HT0. Only if it is judged that the passage time PT0 is within the range of the hold time HT0, the exposure step is performed. Therefore, it is possible to expose the resist layer to light in a desirable manner. Consequently, it is possible to form patterns of uniform line width on substrates K.

Further, judgment is made as to whether the passage time PT1 from the exposure date/time to the start of the development step is within the range of the hold time HT1. Only if the judgment is YES, the development step is performed. Therefore, it is possible to develop the resist layer in a desirable manner. Consequently, it is possible to form circuit patterns of uniform line width on the substrates K.

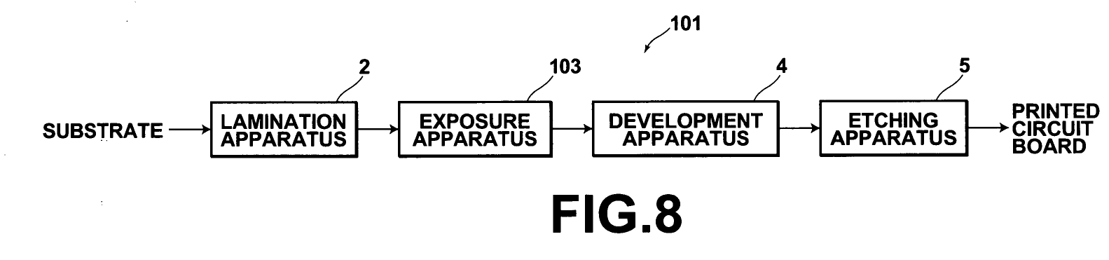

Next, a second embodiment of the present invention will be described. FIG. 8 is a schematic block diagram illustrating the configuration of a system for producing a printed circuit board according to the second embodiment. In the second embodiment, the same reference numerals will be assigned to elements that are the same as those of the first embodiment, and detailed descriptions thereof will be omitted. In the second embodiment, the structure of an exposure apparatus is different from that of the exposure apparatus 3 in the first embodiment. As illustrated in FIG. 8, a system 101 for producing a printed circuit board according to the second embodiment includes the lamination apparatus 2, an exposure apparatus 103, the development apparatus 4 and the etching apparatus 5.

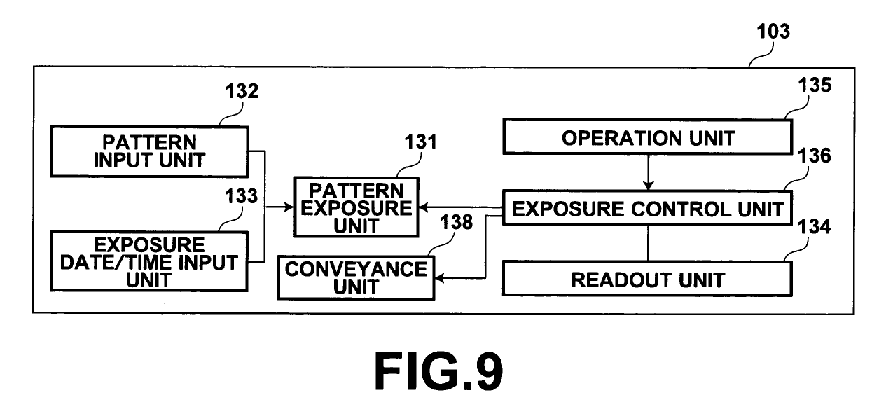

FIG. 9 is a schematic block diagram illustrating the configuration of the exposure apparatus 103 according to the second embodiment. As illustrated in FIG. 9, the exposure apparatus 103 includes a pattern exposure unit 131, a pattern input unit 132, an exposure date/time input unit 133, a readout unit 134, an operation unit 135, an exposure control unit 136 and a conveyance unit 138. The pattern exposure unit 131 exposes the substrate K to light forming a pattern that has the same shape as that of a circuit pattern and to light carrying exposure date/time information representing exposure date/time. The pattern input unit 132 inputs binary pattern data representing a circuit pattern to be formed by exposure to the pattern exposure unit 131. The exposure date/time input unit 133 inputs binary exposure date/time pattern data representing exposure date/time to the pattern exposure unit 131. The readout unit 134 reads out lamination date/time information present on the substrate K. The operation unit 135 is used by an operator to operate the exposure apparatus 103. The exposure control unit 136 controls drive of the exposure apparatus 103. The pattern exposure unit 131, the pattern input unit 132, the exposure date/time input unit 133, the readout unit 134, the operation unit 135 and the conveyance unit 138 have the same functions as those of the pattern exposure unit 31, the pattern input unit 32, the exposure date/time input unit 33, the readout unit 34, the operation unit 35 and the conveyance unit 38 of the first embodiment, respectively. Therefore, detailed description of the elements will be omitted.

The exposure control unit 136 judges, based on a lamination date/time signal output from the readout unit 134, lamination date/time in a manner similar to the judgment in the first embodiment. Further, the exposure control unit 136 includes a clock and obtains passage time PT10 from the lamination date/time to the current date/time. Then, the exposure control unit 136 sets an exposure condition at the pattern exposure unit 131 based on the passage time PT10. Setting of the exposure condition will be described below.

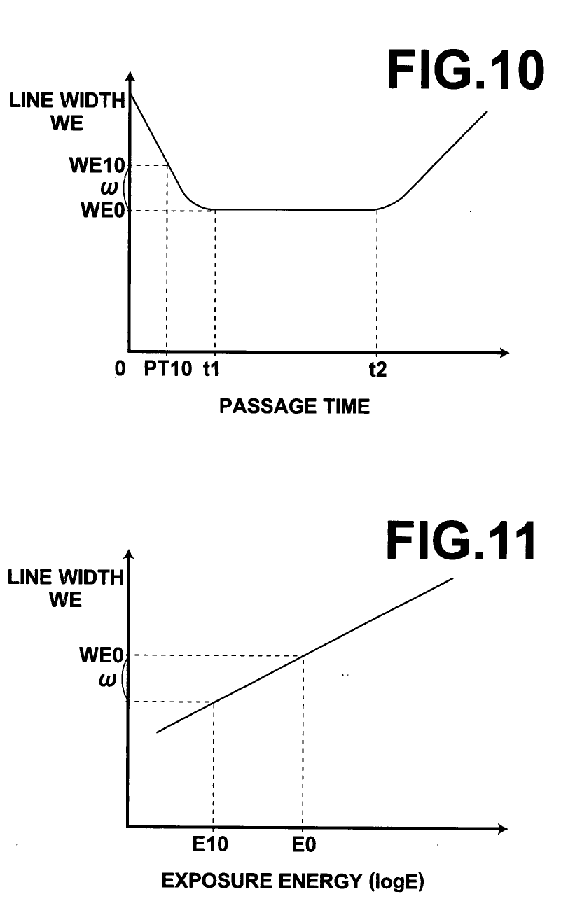

As described above, there is a tendency that the line width of a circuit pattern becomes thick if exposure is performed immediately after the lamination step or if the printed circuit board is kept for long time after the lamination step. FIG. 10 is a diagram illustrating the relationship between passage time after the lamination step and line width WE of a circuit pattern. In an ordinary process for producing printed circuit boards, an exposure condition at the time of exposure, a development condition at the time of development and an etching condition at the time of etching are set. If exposure is performed in a standard exposure condition within the range of predetermined hold time after the lamination step, and if development is performed in a standard exposure condition within the range of predetermined hold time after the exposure step, and if etching is performed in a standard etching condition, it is possible to form a circuit pattern that has line width (hereinafter, referred to as a standard line width) WE0, which is a desirable line width from the design point of view. Production of such a printed circuit board is hereinafter referred to as “production in a standard condition”. The line widths WE in FIG. 10 are the line widths of circuit patterns obtained by producing the circuit patterns in a standard condition while passage time after the lamination step is variously changed.

In FIG. 10, time between t1 and t2 is hold time HT0 in the first embodiment. A circuit pattern that has a standard line width WE0 can be formed by performing exposure at some time within this range of time after the lamination and by producing the printed circuit board in a standard condition after the exposure. Further, if the relationship illustrated in FIG. 10 is referred to, it is possible to know how the line width WE varies depending on passage time that is before or after the hold time.

FIG. 11 is a diagram illustrating the relationship between exposure energy at the time of exposure and the line width of a circuit pattern. As illustrated in FIG. 11, the line width WE of the circuit pattern becomes thicker as the exposure energy becomes larger. In the relationship illustrated in FIG. 11, the line width obtained when the exposure energy is standard exposure energy E0 is standard line width WE0, a desirable line width from the design point of view.

Therefore, if the relationship illustrated in FIG. 10 is referred to, it is possible to obtain, based on passage time PT10, line width WE10 when the passage time is the passage time PT10. Further, it is possible to obtain a line-width variation amount ω by obtaining a difference WE10−WE0, which is a difference from the standard line width WE0. Here, if exposure is performed in a standard exposure condition when the passage time is PT10, and further if development and etching are performed in a standard development condition and in a standard etching condition, respectively, the line width becomes WE10. The line width WE10 is thicker than the standard line width WE0 by the line-width variation amount ω. Therefore, if exposure energy E10 for reducing the line width from the standard line width WE0 by the line-width variation amount ω is obtained with reference to the relationship illustrated in FIG. 11, and if exposure of a pattern is performed at the exposure energy E10, and if after the exposure, production is performed in a standard condition, it is possible to form a circuit pattern that has the standard line width WE0.

The exposure control unit 136 stores the relationships illustrated in FIGS. 10 and 11 as tables. The exposure control unit 136 calculates exposure energy E10 using the passage time PT10. Then, the exposure control unit 136 sets an exposure condition by controlling the output from a light source of the pattern exposure unit 131 so that exposure is performed at the exposure energy E10.

Consequently, if the development apparatus 4 performs development in the standard development condition, and if the etching apparatus 5 performs etching in the standard etching condition after the exposure is performed in the set exposure condition, the line width WE of the circuit pattern becomes the standard line width WE0. Therefore, it is possible to form patterns of uniform line width on printed circuit boards.

Further, instead of controlling the output of the light source of the pattern exposure unit 131, pattern data may be changed so that the line width of a pattern formed by exposure is reduced by the line-width variation amount ω. In this case, the exposure condition should be the standard exposure condition.

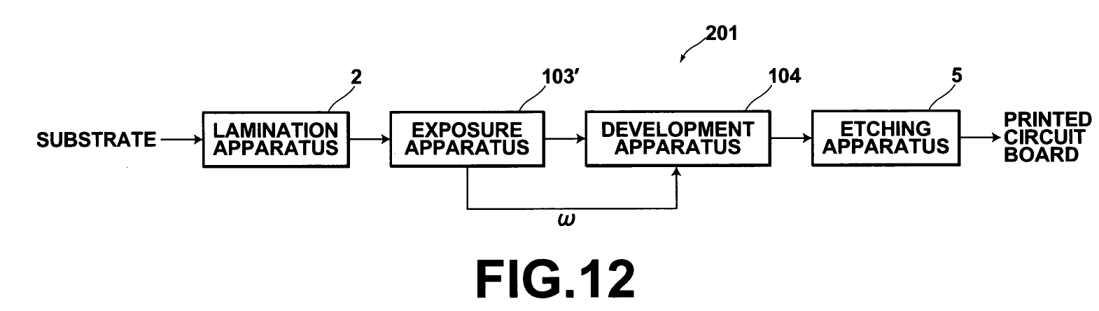

Next, a third embodiment of the present invention will be described. FIG. 12 is a schematic block diagram illustrating the configuration of a system for producing a printed circuit board according to the third embodiment. In the third embodiment, the same reference numerals will be assigned to elements that are the same as those of the first embodiment, and detailed descriptions thereof will be omitted. In the third embodiment, the structures of an exposure apparatus and a development apparatus are different from those of the exposure apparatus 3 and the development apparatus 4 in the first embodiment, respectively. As illustrated in FIG. 12, a system 201 for producing a printed circuit board according to the third embodiment includes the lamination apparatus 2, an exposure apparatus 103′, a development apparatus 104 and the etching apparatus 5.

The exposure apparatus 103′ of the third embodiment does not include a readout unit. Further, the exposure apparatus 103′ has the same function as the exposure apparatus 103 of the second embodiment except that the exposure control unit 136 outputs information representing the line-width variation amount ω to the development apparatus 104 and exposure is performed in the standard exposure condition. Therefore, detailed description of the exposure apparatus 103′ will be omitted.

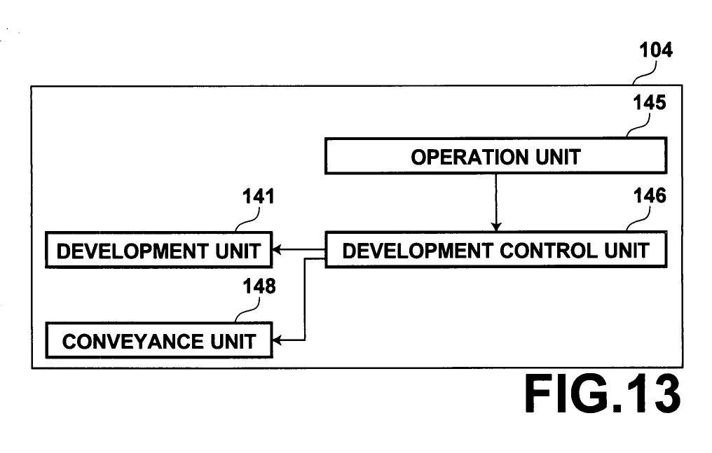

FIG. 13 is a schematic block diagram illustrating the configuration of a development apparatus 104 according to the third embodiment. The development apparatus 104 illustrated in FIG. 13 includes a development unit 141, an operation unit 145, a development control unit 146 and a conveyance unit 148. The development unit 141 develops a substrate K that has been exposed to light. The operation unit 145 is used by an operator to operate the development apparatus 104. The development control unit 146 controls drive of the development apparatus 104. The development unit 141, the operation unit 145 and the conveyance unit 148 have the same functions as those of the development unit 41, the operation unit 45 and the conveyance unit 48 in the development apparatus 4 of the first embodiment, respectively. Therefore, detailed descriptions of the elements will be omitted.

The development control unit 146 sets a development condition based on information representing the line-width variation amount ω output by the exposure apparatus 103′. Setting of the development condition will be described below.

As described above, if after the lamination step, production is performed in a standard condition at some time before or after the hold time, the line width of the circuit pattern becomes thick.

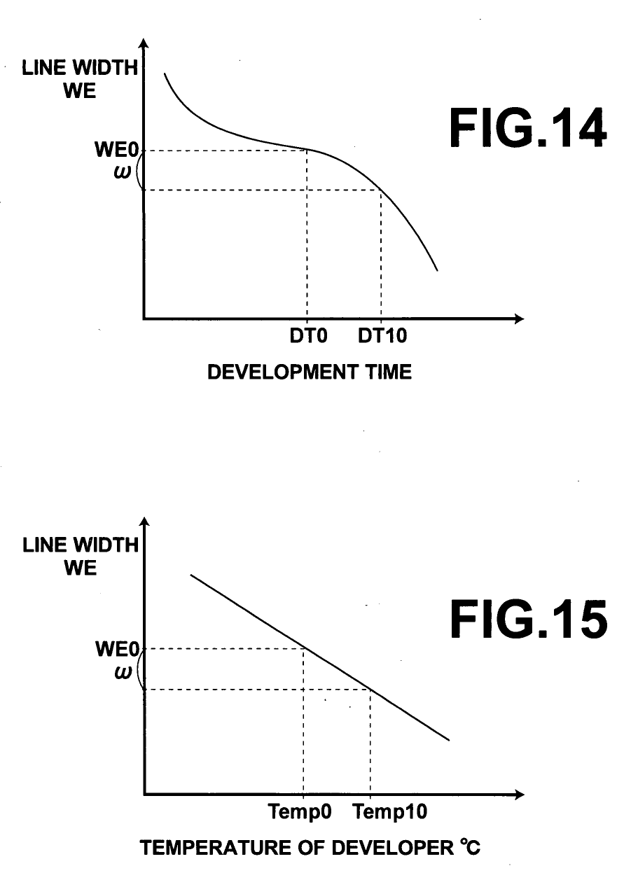

FIG. 14 is a diagram illustrating the relationship between development time and the line width of a circuit pattern. As illustrated in FIG. 14, the line width WE of the circuit pattern becomes thinner as the development time becomes longer. In the relationship illustrated in FIG. 14, a line width WE obtained when the development time is standard development time DT0 is a standard line width WE0, which is a desirable line width from the design point of view.

Therefore, if the relationship illustrated in FIG. 14 is referred to, it is possible to obtain development time DT10 for reducing the line width from the standard line width WE0 by the line-width variation amount ω.

The development control unit 146 stores the relationship illustrated in FIG. 14 as a table, and calculates the development time DT10 based on the line-width variation amount ω input from the exposure apparatus 103′. Then, the development control unit 146 sets a development condition by controlling the development unit 141 so that development is performed for the development time DT10. Specifically, the development control unit 146 controls the conveyance speed of the substrate K.

Accordingly, if exposure is performed in a standard exposure condition in the exposure apparatus 103′, and if etching is performed in a standard etching condition in the etching apparatus 5, the line width WE of the circuit pattern becomes the standard line width WE0. Therefore, it is possible to form circuit patterns of uniform line width on printed circuit boards.

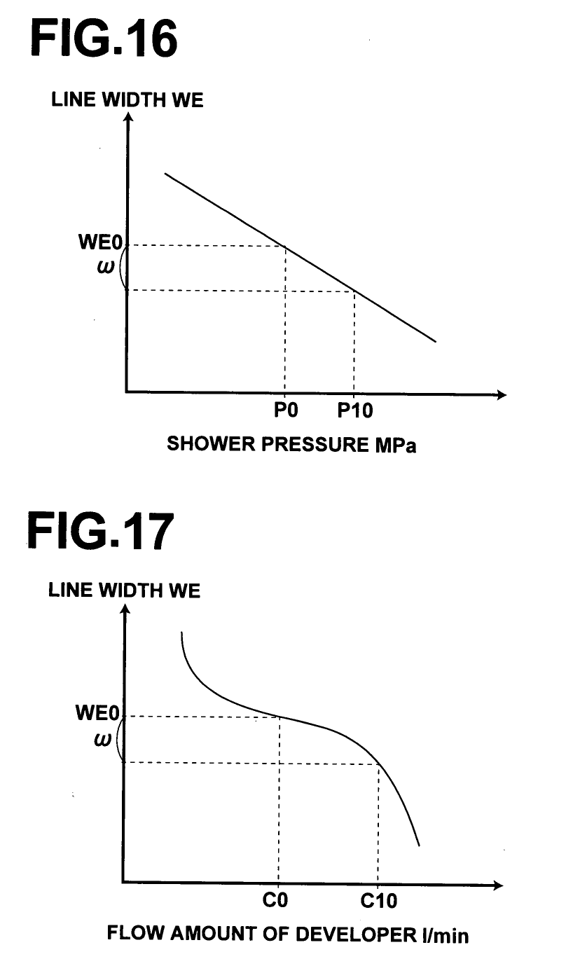

Further, the line widths of circuit patterns vary depending not only on the development time but also on the temperature of the developer, shower pressure at the time when the developer is sprayed on the substrate K and the flow amount of the developer. FIGS. 15 through 17 are diagrams illustrating relationships between the line width WE of a circuit pattern and the temperature of developer, shower pressure when the developer is sprayed on the substrate K and the flow amount of developer, respectively. As illustrated in FIG. 15, the line width WE becomes thinner as the temperature of the developer becomes higher. Further, as illustrated in FIG. 16, the line width WE becomes thinner as the shower pressure becomes higher. Further, as illustrated in FIG. 17, the line width WE becomes thinner as the flow amount of the developer increases. In the relationships illustrated in FIGS. 15 through 17, the line width WE of a circuit pattern obtained when the temperature of the developer is standard developer temperature Temp0, the shower pressure is standard shower pressure P0 and the flow amount of developer is standard developer flow amount C0 is standard line width WE0, which is desirable line width from the design point of view.

Therefore, with reference to the relationships illustrated in FIGS. 15 through 17, it is possible to obtain developer temperature Temp10, shower pressure P10 and developer flow amount C10 for reducing the line width from the standard line width WE0 by the line-width variation amount ω.

Hence, the relationships illustrated in FIG. 15, 16 or 17 may be stored as tables in the development control unit 146. Then, the developer temperature Temp10, the shower pressure P10 or the developer flow amount C10 may be calculated based on the line-width variation amount ω input from the exposure apparatus 103′. Then, development may be performed by adopting the calculated developer temperature Temp10, shower pressure P10 or developer flow amount C10. If a circuit pattern is formed in such a manner, it is possible to form a circuit pattern that has the standard line width WE0.

When one of the development time, the developer temperature, the shower pressure and the developer flow amount is set as the condition, the conditions other than the set condition should be set to standard conditions for obtaining the standard line width WE0.

Alternatively, the development control unit 146 may store a plurality of relationships selected from the relationships illustrated in FIGS. 14 through 17 as tables. Then, the development control unit 146 may perform development by combining the stored relationships and by determining at least two of the development time DT10, the developer temperature Temp10, the shower pressure P10 and the developer flow amount C10.

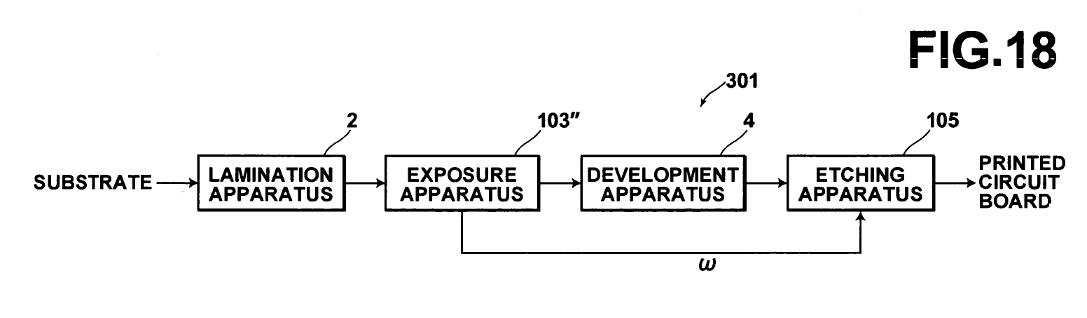

Next, the fourth embodiment of the present invention will be described. FIG. 18 is a schematic block diagram illustrating the configuration of a system for producing a printed circuit board according to the fourth embodiment. In the fourth embodiment, the same reference numerals will be assigned to elements that are the same as those of the first embodiment, and detailed descriptions thereof will be omitted. In the fourth embodiment, the structure of an exposure apparatus is different from that of the exposure apparatus 3 in the first embodiment, and the structure of an etching apparatus is different from that of the etching apparatus 5 in the first embodiment. As illustrated in FIG. 18, a system 301 for producing a printed circuit board according to the fourth embodiment includes the lamination apparatus 2, an exposure apparatus 103″, the development apparatus 4 and an etching apparatus 105.

The function of the exposure apparatus 103″ in the fourth embodiment is the same as the exposure apparatus 103′ in the third embodiment except that the exposure apparatus 103″ outputs information representing the line-width variation amount ω to the etching apparatus 105. Therefore, detailed description of the exposure apparatus 103″ will be omitted.

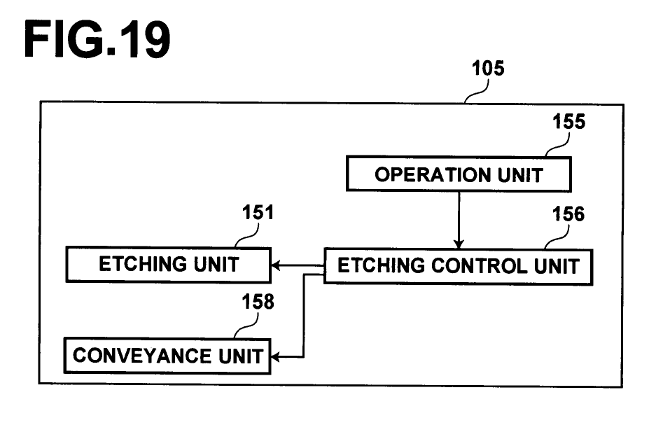

FIG. 19 is a schematic block diagram illustrating the configuration of the etching apparatus 105 according to the fourth embodiment. As illustrated in FIG. 19, the etching apparatus 105 includes an etching unit 151, an operation unit 155, an etching control unit 156 and a conveyance unit 158. The etching unit 151 performs etching on a developed substrate K. The operation unit 155 is used by an operator to operate the etching apparatus 105. The etching control unit 156 controls drive of the etching apparatus 105. The etching unit 151, the operation unit 155 and the conveyance unit 158 have the same functions as those of the etching unit 51, the operation unit 55 and the conveyance unit 58 in the etching apparatus 5 of the first embodiment, respectively. Therefore, detailed description of the elements will be omitted.

The etching control unit 156 sets an etching condition based on the information representing the line-width variation amount ω output from the exposure apparatus 103″. Setting of the etching condition will be described.

As described above, if after the lamination step, production is performed in a standard condition at some time before or after the hold time, the line width of the circuit pattern becomes thick.

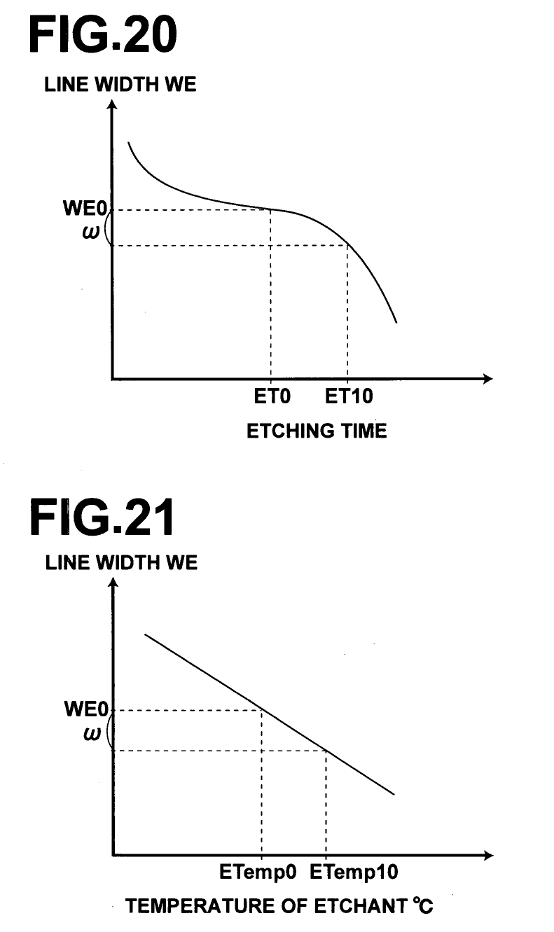

FIG. 20 is a diagram illustrating the relationship between etching time and the line width of a circuit pattern. As illustrated in FIG. 20, the line width WE of the circuit pattern becomes thinner as the etching time becomes longer. In the relationship illustrated in FIG. 20, a line width WE obtained when etching time is standard etching time ET0 is a standard line width WE0, which is a desirable line width from the design point of view.

Therefore, if the relationship illustrated in FIG. 20 is referred to, it is possible to obtain etching time ET10 for reducing the line width from the standard line width WE0 by the line-width variation amount ω.

The etching control unit 156 stores the relationship illustrated in FIG. 20 as a table, and calculates the etching time ET10 based on the line-width variation amount ω input from the exposure apparatus 103″. Then, the etching control unit 156 sets an etching condition by controlling the etching unit 151 so that etching is performed for the etching time ET10. Specifically, the etching control unit 156 controls the conveyance speed of the substrate K.

Accordingly, if exposure is performed in a standard exposure condition in the exposure apparatus 103″, and if development is performed in a standard development condition in the development apparatus 4, the line width becomes the standard line width WE0. Therefore, it is possible to form circuit patterns of uniform line width on printed circuit boards.

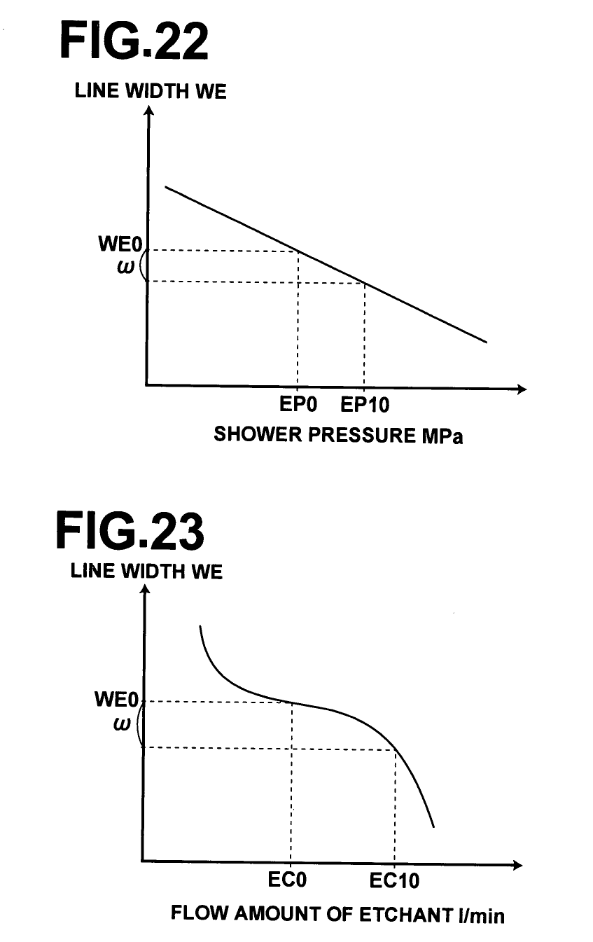

Further, the line widths of circuit patterns vary depending not only on the etching time but also on the temperature of the etchant, shower pressure at the time when the etchant is sprayed on the substrate K and the flow amount of the etchant. FIGS. 21 through 23 are diagrams illustrating relationships between the line width WE of a circuit pattern and the temperature of etchant, shower pressure when the etchant is sprayed on the substrate K and the flow amount of etchant, respectively. As illustrated in FIG. 21, the line width WE becomes thinner as the temperature of the etchant becomes higher. Further, as illustrated in FIG. 22, the line width WE becomes thinner as the shower pressure becomes higher. Further, as illustrated in FIG. 23, the line width WE becomes thinner as the flow amount of the etchant increases. In the relationships illustrated in FIGS. 21 through 23, the line width WE of a circuit pattern obtained when the temperature of the etchant is standard etchant temperature ETemp0, the shower pressure is standard shower pressure EP0 and the flow amount of etchant is standard etchant flow amount EC0 is standard line width WE0, which is desirable line width from the design point of view.

Therefore, with reference to the relationships illustrated in FIGS. 21 through 23, it is possible to obtain etchant temperature ETemp10, shower pressure EP10 and etchant flow amount EC10 for reducing the line width from the standard line width WE0 by the line-width variation amount ω.

Hence, the relationship illustrated in FIG. 21, 22 or 23 may be stored in the etching control unit 156. Then, the etchant temperature ETemp10, the shower pressure EP10 or the etchant flow amount EC10 may be calculated based on the line-width variation amount ω input from the exposure apparatus 103″. Then, etching may be performed by adopting the calculated etchant temperature ETemp10, shower pressure EP10 or etchant flow amount EC10. If a circuit pattern is formed in such a manner, it is possible to form a circuit pattern that has the standard line width WE0.

When one of the etching time, the etchant temperature, the shower pressure and the etchant flow amount is set as the condition, the conditions other than the set condition should be set to standard conditions for obtaining the standard line width WE0.

Alternatively, the etchant control unit 156 may store a plurality of relationships selected from the relationships illustrated in FIGS. 20 through 23 as tables. Then, the etchant control unit 156 may perform etching by combining the stored relationships and by determining at least two of the etching time EDT10, the etchant temperature ETemp10, the shower pressure EP10 and the etchant flow amount EC10.

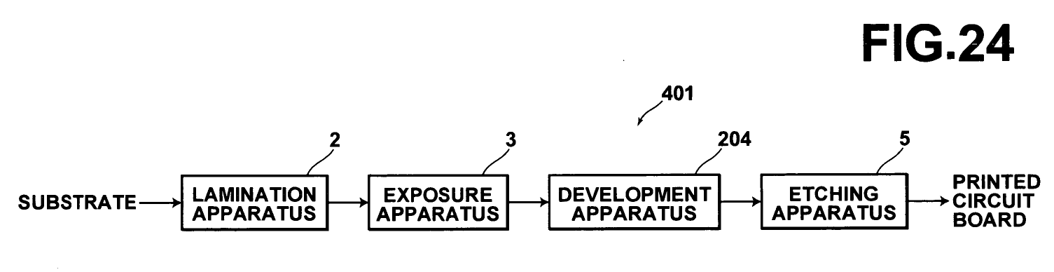

Next, the fifth embodiment of the present invention will be described. FIG. 24 is a schematic block diagram illustrating the configuration of a system for producing a printed circuit board according to the fifth embodiment. In the fifth embodiment, the same reference numerals will be assigned to elements that are the same as those of the first embodiment, and detailed descriptions thereof will be omitted. In the fifth embodiment, the structure of a development apparatus is different from that of the development apparatus 4 of the first embodiment. As illustrated in FIG. 24, a system 401 for producing a printed circuit board according to the fifth embodiment includes the lamination apparatus 2, the exposure apparatus 3, a development apparatus 204 and the etching apparatus 5.

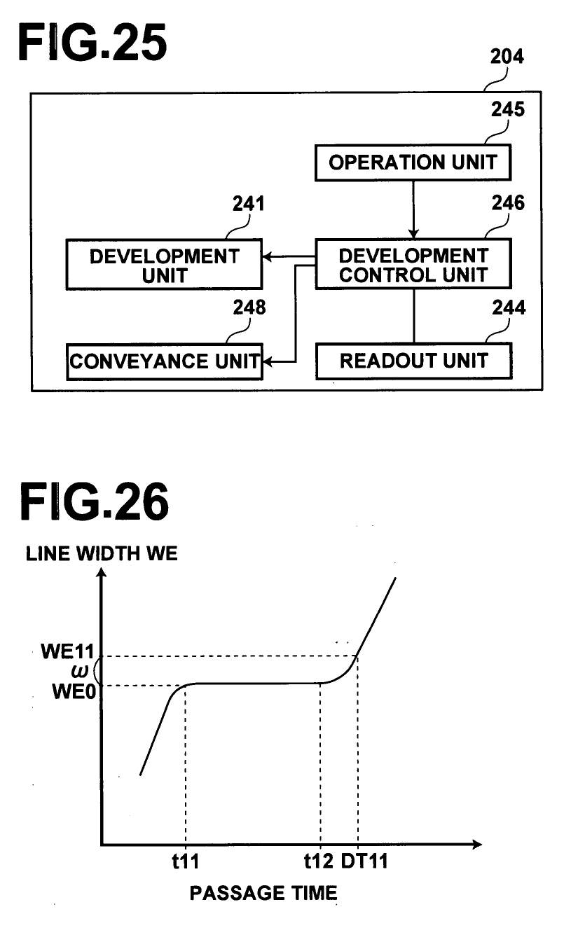

FIG. 25 is a schematic block diagram illustrating the configuration of the development apparatus 204 according to the fifth embodiment. As illustrated in FIG. 25, the development apparatus 204 includes a development unit 241, a readout unit 244, an operation unit 245, a development control unit 246 and a conveyance unit 248. The development unit 241 develops a substrate K that has been exposed to light. The readout unit 244 reads out exposure date/time information present on the substrate K. The operation unit 245 is used by an operator to operate the development apparatus 204. The development control unit 246 controls drive of the development apparatus 204. The development unit 241, the readout unit 244, the operation unit 245 and the conveyance unit 248 have the same functions as the development unit 41, the readout unit 44, the operation unit 45 and the conveyance unit 48 of the development apparatus 4 in the first embodiment. Therefore, detailed description of these elements will be omitted.

The development control unit 246 judges, based on an exposure date/time signal output from the readout unit 244, exposure date/time in a manner similar to the judgment in the first embodiment. Further, the development control unit 246 includes a clock and obtains passage time PT11 from the exposure date/time to the current date/time. Then, the development control unit 246 sets a development condition at the development unit 241 based on the passage time PT11.

As described above, there are tendencies that the line width of a pattern becomes thin if development is performed immediately after the exposure step and that the line width of the pattern becomes thick if a printed circuit board is kept for long time after the exposure step. FIG. 26 is a diagram illustrating the relationship between passage time after the exposure step and line width WE of a pattern. The line width WE in FIG. 26 is line width of circuit patterns obtained by producing printed circuit boards in a standard condition while passage time after the exposure step is variously changed.

In FIG. 26, time between t11 and t12 is hold time HT1 in the first embodiment. A pattern that has a standard line width WE0 can be formed by performing exposure in a standard exposure condition, by performing development within the range of time after the exposure, and by performing etching in a standard etching condition after the development. Further, if the relationship illustrated in FIG. 26 is referred to, it is possible to know how the line width WE varies depending on passage time that is before or after the hold time.

Therefore, if the relationship illustrated in FIG. 26 is referred to, it is possible to obtain, based on passage time DT11, line width WE11 when the passage time is the passage time DT11. Further, it is possible to obtain a line-width variation amount ω by obtaining a difference WE11-WE0, which is a difference from the standard line width WE0. Here, if exposure is performed in a standard exposure condition when the passage time is DT11, and further if exposure and etching are performed in a standard etching condition, the line width becomes WE11. The line width WE11 is thicker than the standard line width WE0 by the line-width variation amount ω. Therefore, development time DT10 for changing the line width from the standard line width WE0 by the line-width variation amount ω is obtained with reference to the relationship between the development time and the line width WE illustrated in FIG. 14. If development is performed by adopting the development time DT10, and if exposure and etching are performed in a standard exposure condition and a standard etching condition, respectively, it is possible to form a pattern that has the standard line width WE0.

The development control unit 246 stores the relationships illustrated in FIGS. 26 and 14 as tables. The development control unit 246 calculates development time DT11 using the calculated line-width variation amount ω. Then, the development control unit 246 sets a development condition by controlling the development unit 241 so that development is performed by adopting the development time DT11. Specifically, the conveyance speed of the substrate K is controlled.

Consequently, if the exposure apparatus 3 performs exposure in the standard exposure condition and the etching unit 5 performs etching in the standard etching condition, the line width becomes the standard line width WE0. Therefore, it is possible to form circuit patterns of uniform line width on printed circuit boards.

Meanwhile, the relationship illustrated in FIG. 15, FIG. 16 or FIG. 17 may be stored as a table in the development control unit 246. Then, the developer temperature Temp11, the shower pressure P11 or the developer flow amount C11 may be calculated based on the calculated line-width variation amount ω. Then, development may be performed by adopting the calculated developer temperature Temp11, shower pressure P11 or developer flow amount C11. If a circuit pattern is formed in such a manner, it is possible to form a circuit pattern that has the standard line width WE0.

The development control unit 246 may store a plurality of relationships selected from the relationships illustrated in FIGS. 14 through 17 as tables. Then, the development control unit 246 may perform development by combining the stored relationships and by determining at least two of the development time DT11, developer temperature Temp11, the shower pressure P11 and the developer flow amount C11.

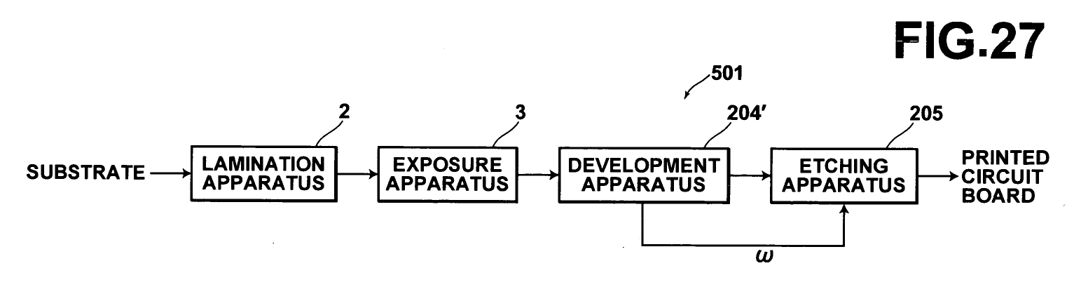

Next, the sixth embodiment of the present invention will be described. FIG. 27 is a schematic block diagram illustrating the configuration of a system for producing a printed circuit board according to the sixth embodiment. In the sixth embodiment, the same reference numerals will be assigned to elements that are the same as those of the first embodiment, and detailed descriptions thereof will be omitted. In the sixth embodiment, the structure of a development apparatus is different from that of the development apparatus 4 of the first embodiment, and the structure of an etching apparatus is different from that of the etching apparatus 5 of the first embodiment. As illustrated in FIG. 27, a system 501 for producing a printed circuit board according to the sixth embodiment includes the lamination apparatus 2, the exposure apparatus 3, a development apparatus 204′ and an etching apparatus 205.

The function of the development apparatus 204′ in the sixth embodiment is the same as the development apparatus 204 in the fifth embodiment except that the development apparatus 204′ does not have a readout unit and that the development control unit 246 outputs information representing the line-width variation amount ω to the etching apparatus 205 and that exposure is performed in a standard exposure condition. Therefore, detailed description of the development apparatus 204′ will be omitted.

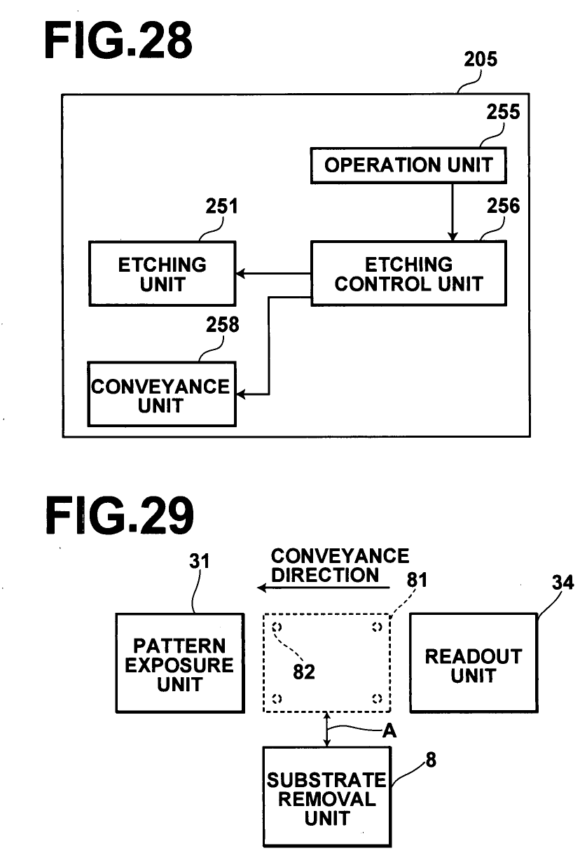

FIG. 28 is a schematic block diagram illustrating the configuration of the etching apparatus 205 according to the sixth embodiment. As illustrated in FIG. 28, the etching apparatus 205 includes an etching unit 251, an operation unit 255, an etching control unit 256 and a conveyance unit 258. The etching unit 251 performs etching on a developed substrate K. The operation unit 255 is used by an operator to operate the etching apparatus 205. The etching control unit 256 controls drive of the etching apparatus 205. The etching unit 251, the operation unit 255 and the conveyance unit 258 have the same functions as those of the etching unit 51, the operation unit 55 and the conveyance unit 58 in the etching apparatus 5 of the first embodiment, respectively. Therefore, detailed descriptions of the elements will be omitted.

The etching control unit 256 sets an etching condition based on the information representing the line-width variation amount ω output from the development apparatus 204′ in a manner similar to the setting at the etching apparatus 105 of the fourth embodiment.

Specifically, at least one of the relationships illustrated in FIGS. 20 through 23 is stored as a table in the etching control unit 256. Then, etching is performed, based on information representing the line-width variation amount ω output from the development apparatus 204′, by combining the stored relationships and by determining at least two of the etching time EDT11, etchant temperature ETemp11, the shower pressure EP11 and the etchant flow amount EC11.

Accordingly, if exposure is performed in a standard exposure condition in the exposure apparatus 3, and if development is performed in a standard development condition in the development apparatus 204′, the line width becomes the standard line width WE0. Therefore, it is possible to form circuit patterns of uniform line width on printed circuit boards.

In the first embodiment, judgment is made as to whether the passage time PT0 from the lamination date/time to date/time when exposure is going to be performed is within the range of hold time HT0. Further, judgment is made as to whether the passage time PT1 from the exposure date/time to date/time when development is going to be performed is within the range of hold time HT1. If these judgments are NO, warnings are issued. Instead of issuing warnings, the substrate K may be removed from the exposure step and the development step. This embodiment will be described below as the seventh embodiment.

A system for producing a printed circuit board according to the seventh embodiment is different from the system 101 for producing a printed circuit board according to the first embodiment in that the exposure apparatus 3 and the development apparatus 4 in the system according to the seventh embodiment include a substrate removal means for removing the substrate K from the exposure apparatus 3 if the judgment is NO and a substrate removal means for removing the substrate K from the development apparatus 4 if the judgment is NO, respectively.

The structure of the substrate removal means in the exposure apparatus 3 and that of the substrate removal means in the development apparatus 4 are the same. Therefore, only the substrate removal means provided at the exposure apparatus 3 will be described.

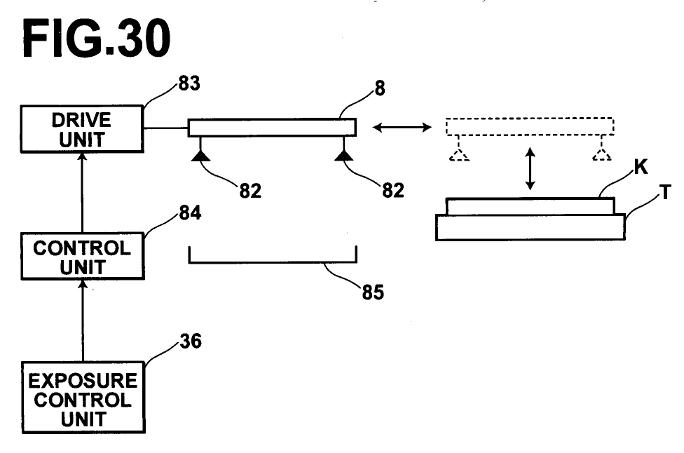

FIG. 29 is a diagram illustrating placement of the substrate removal unit. FIG. 30 is a diagram illustrating the configuration of the substrate removal unit, viewed from the upstream side of a conveyance direction illustrated in FIG. 29. A substrate removal unit 8 is placed on a side of the conveyance path between the readout unit 34 and the pattern exposure unit 31. The substrate removal unit 8 includes a stage 81, suckers 82, a drive unit 83, a control unit 84 and a discard unit 85. The stage 81 is provided on the upper side of the conveyance path between the readout unit 34 and the pattern exposure unit 31, and the stage 81 is movably set so as to move forward and backward as arrow A shows. The suckers 82 are provided in the vicinities of four corners of the stage 81. The drive unit 83 drives the stage 81 and the suckers 82. The control unit 84 controls the drive unit 83, and the discard unit 85 discards the removed substrate K.

The drive unit 83 includes a mechanism for moving the stage 81 forward and backward between the initial position on a side of the conveyance path and a position on the upper side of the conveyance path (hereinafter, referred to as a drive position). The drive unit 83 also includes a mechanism for moving the stage 81 forward and backward between the position on the upper side of the conveyance path and the position of the substrate K placed on table T. The drive unit 83 also includes a mechanism for applying negative pressure to the suckers 82 so that the substrate K is sucked by the suckers 82.

If the exposure control unit 36 judges that the passage time PT0 is not within the range of the predetermined hold time HT0, the control unit 84 receives a signal indicating the judgment result and controls drive of the drive unit 83 so that the substrate K is removed from the table T. Further, if the exposure control unit 36 judges that the passage time PT0 is not within the range of the predetermined hold time HT0, the control unit 84 controls drive of the conveyance unit 38 so that the table T stops between the readout unit 34 and the pattern exposure unit 31.

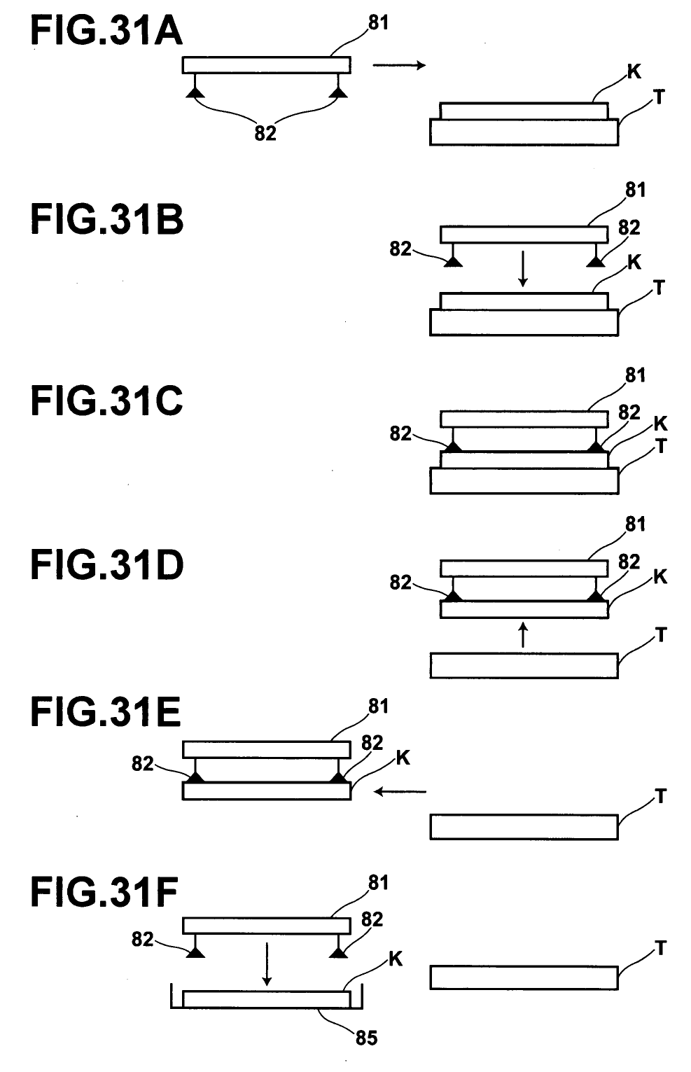

The operation of the substrate removal unit 8 will be described. FIG. 31 is a diagram illustrating the operation of the substrate removal unit 8. Here, only the stage 81 and the suckers 82 of the substrate removal unit 8 are illustrated. First, if the control unit 84 receives a signal indicating that the passage time PT0 is not within the range of predetermined hold time HT0, the drive unit 83 moves the stage 81 from the initial position illustrated in FIG. 31A to the drive position illustrated in FIG. 31B. Next, the stage 81 moves downward until the suckers 82 touch the substrate K. When the suckers 82 touch the substrate K, negative pressure is applied to the suckers 82 and the substrate K is sucked by the suckers 82 (FIG. 31C). Next, as illustrated in FIG. 31D, the stage 81 moves upward together with the substrate K and returns to the initial position, as illustrated in FIG. 31E. When the stage 81 moves to the initial position, the negative pressure applied to the suckers 82 is released. Then, the substrate K is discarded and put in the discard unit 85, as illustrated in FIG. 31F, and the processing ends.

As described above, in the seventh embodiment, judgment is made as to whether the passage time PT0 from the lamination date/time to date/time when exposure is going to be performed is within the range of the hold time HT0. Further, judgment is made as to whether the passage time PT1 from the exposure date/time to date/time when development is going to be performed is within the range of the hold time HT1. If these judgments are NO, the substrate K is removed from the conveyance path. Therefore, it is possible to perform the exposure step and the development step only when the judgments are YES. Hence, it is possible to perform desirable exposure and development on the resist layer. Consequently, it is possible to form circuit patterns of uniform line width on the substrates K.

In the aforementioned embodiments, laser light sources were used as light sources of the lamination apparatus 2, the exposure apparatus 3 and the like. Alternatively, mercury lamps may be used as the light sources.

In the first embodiment, judgment was made both in the exposure step and in the development step. Judgment was made as to whether the passage time PT0 from the lamination date/time to date/time when exposure is going to be performed is within the range of the hold time HT0. Further, judgment was made as to whether the passage time PT1 from the exposure date/time to date/time when development is going to be performed is within the range of the hold time HT1. Alternatively, the judgment may be made only in one of the exposure step and the development step.

Further, in the aforementioned embodiments, when the substrate is exposed to light carrying exposure date/time information, exposure to the light carrying exposure date/time information is performed at the same as exposure to light in a pattern that has the same shape as the circuit pattern. Alternatively, the substrate may be exposed to light carrying exposure date information after the substrate is exposed to light in the pattern but before the development step is performed.

Further, in the aforementioned embodiments, a case, in which the resist layer is superposed on the substrate and exposure, development and etching are performed on the resist layer, has been described. However, it is needless to say that the method and the apparatus for producing a printed circuit board of the present invention can be also applied to a case, in which a solder resist layer is superposed on the substrate after a circuit pattern is formed on the substrate and exposure and development are performed on the solder resist layer.

1. A method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:
exposing a predetermined area of the photosensitive layer to light carrying lamination date/time information, the information representing date/time when the lamination step was performed;
judging, by reading out the lamination date/time information, whether passage time after the date/time when the lamination step was performed, the date/time being represented by the read lamination date/time information, is within the range of predetermined hold time; and
controlling the exposure step so that the exposure step is performed only if the judgment is YES.

2. A method for producing a printed circuit board, as defined in claim 1, the method characterized in that the step of controlling is a step of issuing a predetermined warning if the judgment is NO.

3. A method for producing a printed circuit board, as defined in claim 1, the method characterized in that the step of controlling is a step of stopping conveyance of the substrate to the exposure step if the judgment is NO.

4. A method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:
exposing a predetermined area of the photosensitive layer to light carrying exposure date/time information, the information representing date/time when the exposure step was performed;
judging, by reading out the exposure date/time information, whether passage time after the date/time when the exposure step was performed, the date/time being represented by the read exposure date/time information, is within the range of predetermined hold time; and
controlling the development step so that the development step is performed only if the judgment is YES.

5. A method for producing a printed circuit board, as defined in claim 4, the method characterized in that the step of controlling is a step of issuing a predetermined warning if the judgment is NO.

6. A method for producing a printed circuit board, as defined in claim 4, the method characterized in that the step of controlling is a step of stopping conveyance of the substrate to the development step if the judgment is NO.

7. A method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:
exposing a predetermined area of the photosensitive layer to light carrying lamination date/time information, the information representing date/time when the lamination step was performed;
obtaining, by reading out the lamination date/time information, passage time from the date/time when the lamination step was performed, the date/time being represented by the read lamination date/time information, to the start of the exposure step; and
setting, based on the length of the passage time, an exposure condition in the exposure step.

8. A method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:
exposing a predetermined area of the photosensitive layer to light carrying lamination date/time information, the information representing date/time when the lamination step was performed;
obtaining, by reading out the lamination date/time information, passage time from the date/time when the lamination step was performed, the date/time being represented by the read lamination date/time information, to the start of the exposure step; and
setting, based on the length of the passage time, a development condition in the development step.

9. A method for producing a printed circuit board, the method comprising a lamination step for superposing a photosensitive layer on a conductive layer on a substrate, an exposure step for exposing the photosensitive layer to light in a predetermined pattern, a development step for developing the photosensitive layer that has been exposed to light in the pattern and an etching step for forming a circuit pattern including the predetermined pattern by etching the conductive layer on the substrate after the development, the method characterized by comprising the steps of:
exposing a predetermined area of the photosensitive layer to light carrying lamination date/time information, the information representing date/time when the lamination step was performed;
obtaining, by reading out the lamination date/time information, passage time from the date/time when the lamination step was performed, the date/time being represented by the read lamination date/time information, to the start of the exposure step; and
setting, based on the length of the passage time, an etching condition in the etching step.

10. A method for producing a printed circuit board, the method comprising a lamination step for superposing a photosensitive layer on a conductive layer on a substrate, an exposure step for exposing the photosensitive layer to light in a predetermined pattern and a development step for developing the photosensitive layer that has been exposed to light in the pattern, the method characterized by comprising the steps of:
exposing a predetermined area of the photosensitive layer to light carrying exposure date/time information, the information representing date/time when the exposure step was performed;
obtaining, by reading out the exposure date/time information, passage time from the date/time when the exposure step was performed, the date/time being represented by the read exposure date/time information, to the start of the development step; and
setting, based on the length of the passage time, a development condition in the development step.

11. A method for producing a printed circuit board, the method comprising a lamination step for superposing a photosensitive layer on a conductive layer on a substrate, an exposure step for exposing the photosensitive layer to light in a predetermined pattern, a development step for developing the photosensitive layer that has been exposed to light in the pattern and an etching step for forming a circuit pattern including the predetermined pattern by etching the conductive layer on the substrate after the development, the method characterized by comprising the steps of:
exposing a predetermined area of the photosensitive layer to light carrying exposure date/time information, the information representing date/time when the exposure step was performed;
obtaining, by reading out the exposure date/time information, passage time from the date/time when the exposure step was performed, the date/time being represented by the read exposure date/time information, to the start of the development step; and
setting, based on the length of the passage time, an etching condition in the etching step.

12. An apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the lamination means includes a means for exposing a predetermined area of the photosensitive layer to light carrying lamination date/time information, the information representing date/time when the lamination was performed, and wherein the exposure means includes a means for judging, by reading out the lamination date/time information, whether passage time after the date/time when the lamination was performed, the date/time being represented by the read lamination date/time information, is within the range of predetermined hold time and a means for controlling the exposure means so that the exposure means performs the exposure only if the judgment is YES.

13. An apparatus for producing a printed circuit board, as defined in claim 12, the apparatus characterized in that the means for controlling includes a means for issuing a predetermined warning if the judgment is NO.

14. An apparatus for producing a printed circuit board, as defined in claim 12, the apparatus characterized in that the means for controlling includes a means for stopping conveyance of the substrate to the exposure means if the judgment is NO.

15. An apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the exposure means includes a means for exposing a predetermined area of the photosensitive layer to light carrying exposure date/time information, the information representing date/time when the exposure was performed, and wherein the development means includes a means for judging, by reading out the exposure date/time information, whether passage time after the date/time when the exposure was performed, the date/time being represented by the read exposure date/time information, is within the range of predetermined hold time and a means for controlling the development means so that the development means performs the development only if the judgment is YES.

16. An apparatus for producing a printed circuit board, as defined in claim 15, the apparatus characterized in that the means for controlling includes a means for issuing a predetermined warning if the judgment is NO.

17. An apparatus for producing a printed circuit board, as defined in claim 15, the apparatus characterized in that the means for controlling includes a means for stopping conveyance of the substrate to the development means if the judgment is NO.

18. An apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the lamination means includes a means for exposing a predetermined area of the photosensitive layer to light carrying lamination date/time information, the information representing date/time when the lamination was performed, and wherein the exposure means includes a means for obtaining, by reading out the lamination date/time information, passage time from the date/time when the lamination was performed, the date/time being represented by the read lamination date/time information, to the start of the exposure and a means for setting, based on the length of the passage time, an exposure condition at the exposure means.

19. An apparatus for producing a printed circuit board, the apparatus comprising a lamination means for superposing a photosensitive material on a conductive layer on a substrate, an exposure means for exposing the photosensitive layer to light in a predetermined pattern and a development means for developing the photosensitive layer that has been exposed to light in the pattern, the apparatus characterized in that the lamination means includes a means for exposing a predetermined area of the photosensitive layer to light carrying lamination date/time information, the information representing date/time when the lamination was performed, and wherein the exposure means includes a means for obtaining, by reading out the lamination date/time information, passage time from the date/time when the lamination was performed, the date/time being represented by the read lamination date/time information, to the start of the exposure, and wherein the development means includes a means for setting, based on the length of the passage time, a development condition at the development means.

20. An apparatus for producing a printed circuit board, the apparatus comprising a lamination means for superposing a photosensitive layer on a conductive layer on a substrate, an exposure means for exposing the photosensitive layer to light in a predetermined pattern, a development means for developing the photosensitive layer that has been exposed to light in the pattern and an etching means for forming a circuit pattern including the predetermined pattern by etching the conductive layer on the substrate after the development, the apparatus characterized in that the lamination means includes a means for exposing a predetermined area of the photosensitive layer to light carrying lamination date/time information, the information representing date/time when the lamination was performed, and wherein the exposure means includes a means for obtaining, by reading out the lamination date/time information, passage time from the date/time when the lamination was performed, the date/time being represented by the read lamination date/time information, to the start of the exposure, and wherein the etching means includes a means for setting, based on the length of the passage time, an etching condition at the etching means.

21. An apparatus for producing a printed circuit board, the apparatus comprising a lamination means for superposing a photosensitive layer on a conductive layer on a substrate, an exposure means for exposing the photosensitive layer to light in a predetermined pattern and a development means for developing the photosensitive layer that has been exposed to light in the pattern, the apparatus characterized in that the exposure means includes a means for exposing a predetermined area of the photosensitive layer to light carrying exposure date/time information, the information representing date/time when the exposure was performed, and wherein the development means includes a means for obtaining, by reading out the exposure date/time information, passage time from the date/time when the exposure was performed, the date/time being represented by the read exposure date/time information, to the start of the development and a means for setting, based on the length of the passage time, a development condition at the development means.

22. An apparatus for producing a printed circuit board, the apparatus comprising a lamination means for superposing a photosensitive layer on a conductive layer on a substrate, an exposure means for exposing the photosensitive layer to light in a predetermined pattern, a development means for developing the photosensitive layer that has been exposed to light in the pattern and an etching means for forming a circuit pattern including the predetermined pattern by etching the conductive layer on the substrate after the development, the apparatus characterized in that the exposure means includes a means for exposing a predetermined area of the photosensitive layer to light carrying exposure date/time information, the information representing date/time when the exposure was performed, and wherein the development means includes a means for obtaining, by reading out the exposure date/time information, passage time from the date/time when the exposure was performed, the date/time being represented by the read exposure date/time information, to the start of the development, and wherein the etching means includes a means for setting, based on the length of the passage time, an etching condition at the etching means.
